(19) United States
(12) Patent Application Publication
(10) Pub. No.: US 2024/0105566 A1
(43) Pub. Date: Mar. 28, 2024

(54) SEMICONDUCTOR DEVICE

(71) Applicant: ROHM CO., LTD., Kyoto-shi (JP)

(72) Inventors: Xiaopeng WU, Kyoto-shi (JP); Kohei TANIKAWA, Kyoto-shi (JP)

(21) Appl. No.: 18/501,436

(22) Filed: Nov. 3, 2023

Related U.S. Application Data
(63) Continuation of application No. PCT/JP2022/023070, filed on Jun. 8, 2022.

(30) Foreign Application Priority Data
Jun. 24, 2021 (JP) 2021-105049

(51) Int. Cl. H01L 23/498; H01L 23/31; H01L 25/07

(52) U.S. Cl. CPC H01L 23/49811; H01L 23/3121; H01L 23/49844; H01L 25/072; H01L 24/32

(57) ABSTRACT

A semiconductor device includes a terminal, a signal substrate, a supporting conductor and a bonding layer. The terminal includes an electrically conductive tubular holder and a metal pin inserted into the holder. The signal substrate includes a wiring layer and an insulating substrate. The supporting conductor supports the wiring layer via the insulating substrate. The bonding layer is interposed between the supporting substrate and the signal substrate. The insulating substrate includes an obverse surface and a reverse surface spaced apart in a thickness direction of the signal substrate. The wiring layer is disposed on the obverse surface, and the terminal is secured to the wiring layer. The holder is bonded to the wiring layer. The metal pin extends in the thickness direction. The bonding layer electrically insulates the signal substrate and the supporting conductor.

### TECHNICAL FIELD

The present disclosure relates to semiconductor devices.

### BACKGROUND ART

Conventionally, semiconductor devices provided with power switching elements, such as metal-oxide-semiconductor field-effect transistors (MOSFETs) and insulated gate bipolar transistors (IGBT), have been known. These semiconductor devices are used in various electronics, ranging from industrial devices to home appliances and information terminals, or even to vehicle-mount devices. JP-A-2015-126342 discloses a conventional semiconductor device (a power module). The power module disclosed in JP-A-2015-126342 includes a plurality of transistors, a main substrate, a signal substrate and a plurality of signal terminals. The transistors are disposed on the main substrate. The signal substrate is disposed on the main substrate. The signal substrate has signal wiring patterns disposed thereon. The signal wiring patterns include a gate signal wiring pattern and a source sense signal wiring pattern. The signal terminals are bonded to the signal wiring patterns disposed on the signal substrate. The signal terminals include a gate terminal bonded to the gate signal wiring pattern and a source sense terminal bonded to the source sense signal wiring pattern.

### BRIEF DESCRIPTION OF THE DRAWINGS

FIG. 1 is a perspective view of a semiconductor device according to the present disclosure.

FIG. 2 is a perspective view similar to FIG. 1 but omitting a plurality of wires and a resin member.

FIG. 3 is a perspective view similar to FIG. 2 but omitting a first conductive member.

FIG. 4 is a plan view of a semiconductor device according to the present disclosure.

FIG. 5 is a plan view similar to FIG. 4, with the resin member indicated by imaginary lines.

FIG. 6 is a right-side view of a semiconductor device according to the present disclosure, with the resin member indicated by imaginary lines.

FIG. 7 is a left-side view of a semiconductor device according to the present disclosure, with the resin member indicated by imaginary lines.

FIG. 8 is a plan view similar to FIG. 5, with the resin member and the first conductive member omitted and a second conductive member indicated by imaginary lines.

FIG. 9 is a right-side view of a semiconductor device according to the present disclosure.

FIG. 10 is a bottom view of a semiconductor device according to the present disclosure.

FIG. 11 is a sectional view taken along line XI-XI of FIG. 5.

FIG. 12 is a sectional view taken along line XII-XII of FIG. 5.

FIG. 13 is a partially enlarged view of FIG. 12.

FIG. 14 is a partially enlarged view of FIG. 12.

FIG. 15 is a sectional view taken along line XV-XV of FIG. 5.

FIG. 16 is a sectional view taken along line XVI-XVI of FIG. 5.

FIG. 17 is a sectional view taken along line XVII-XVII of FIG. 5.

FIG. 18 is a sectional view taken along line XVIII-XVIII of FIG. 5.

FIG. 19 is a partially enlarged sectional view of a semiconductor device according to a first variation of the present disclosure, showing a portion of the section corresponding to that shown in FIG. 12.

FIG. 20 is a partially enlarged sectional view of a semiconductor device according to a second variation of the present disclosure, showing a portion of the section corresponding to that shown in FIG. 12.

FIG. 21 is a partially enlarged sectional view of a semiconductor device according to a third variation of the present disclosure, showing a portion of the section corresponding to that shown in FIG. 12.

FIG. 22 is a partially enlarged sectional view of a semiconductor device according to a fourth variation of the present disclosure, showing a portion of the section corresponding to that shown in FIG. 12.

### DETAILED DESCRIPTION OF EMBODIMENTS

The following describes preferred embodiments of a semiconductor device according to the present disclosure with reference to the drawings. In the following description, the same or similar elements are denoted by the same reference signs and redundant descriptions of such elements are omitted. In the present disclosure, terms such as “first”, “second”, “third” and so on are used merely as labels and not intended to impose ordinal requirements on the objects referred to by these terms.

In the description of the present disclosure, the expression “An object A is formed in an object B”, and “An object A is formed on an object B” imply the situation where, unless otherwise specifically noted, “the object A is formed directly in or on the object B”, and “the object A is formed in or on the object B, with something else interposed between the object A and the object B”. Likewise, the expression “An object A is arranged in an object B”, and “An object A is arranged on an object B” imply the situation where, unless otherwise specifically noted, “the object A is arranged directly in or on the object B”, and “the object A is arranged in or on the object B, with something else interposed between the object A and the object B”. Further, the expression “An object A is located on an object B” implies the situation where, unless otherwise specifically noted, “the object A is located on the object B, in contact with the object B”, and “the object A is located on the object B, with something else interposed between the object A and the object B”. Still further, the expression “An object A overlaps with an object B as viewed in a certain direction” implies the situation where, unless otherwise specifically noted, “the object A overlaps with the entirety of the object B”, and “the object A overlaps with a part of the object B”.

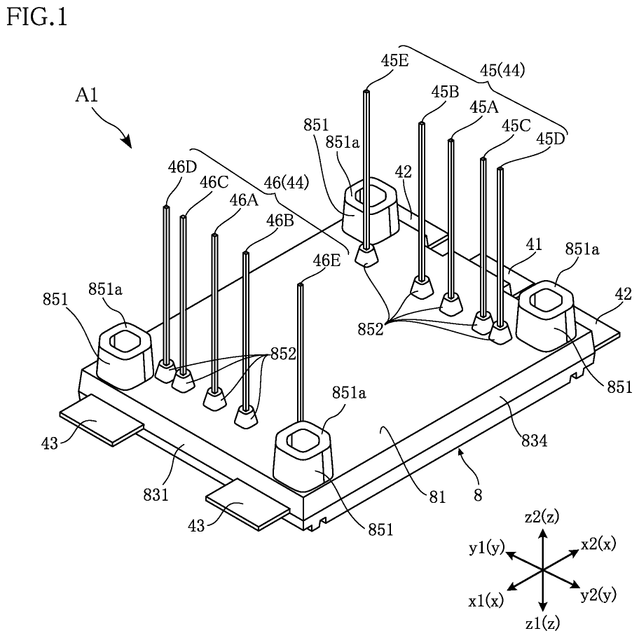

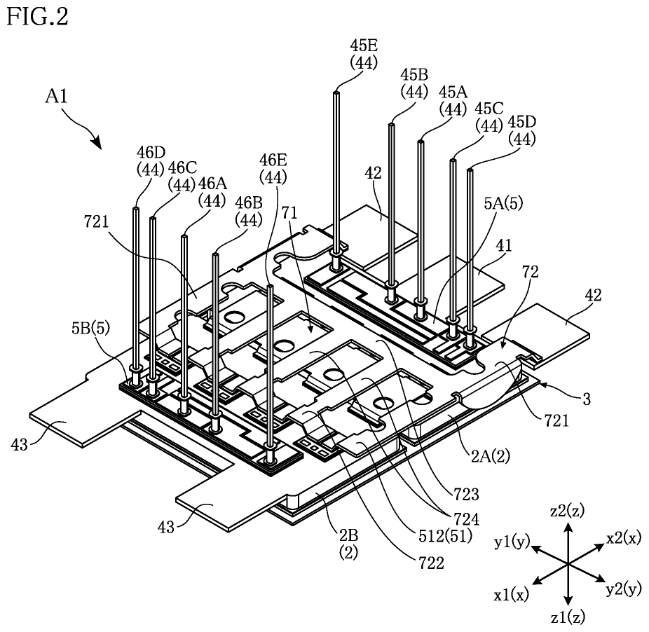

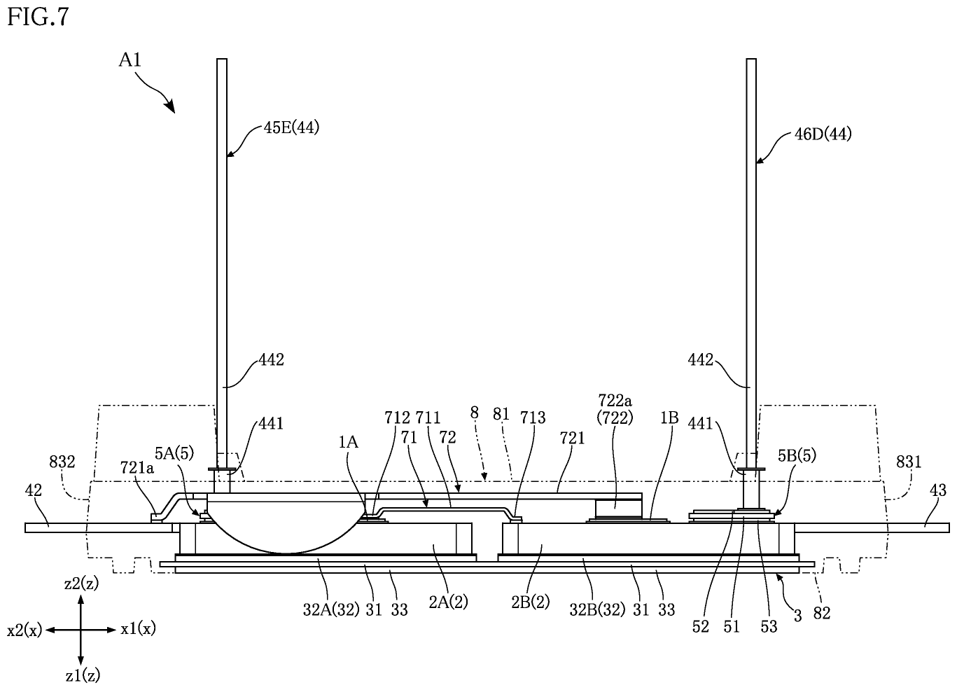

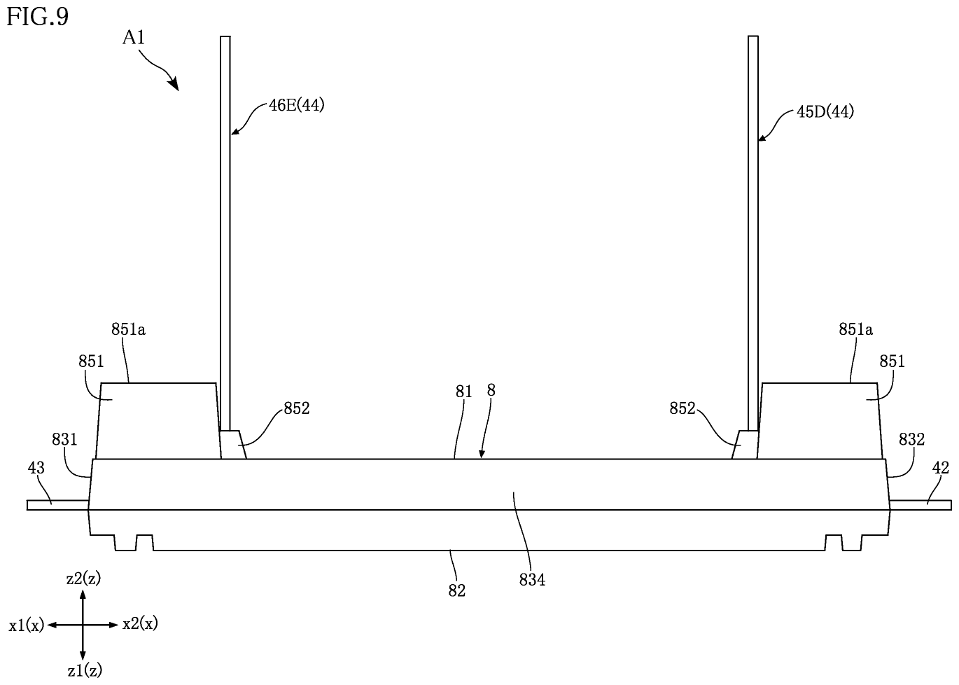

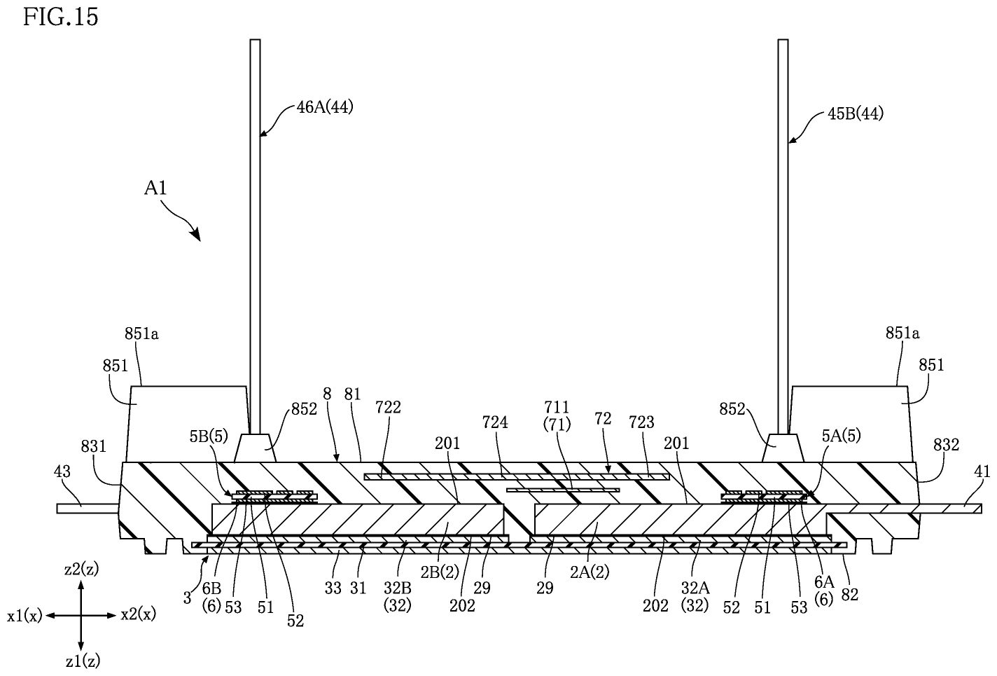

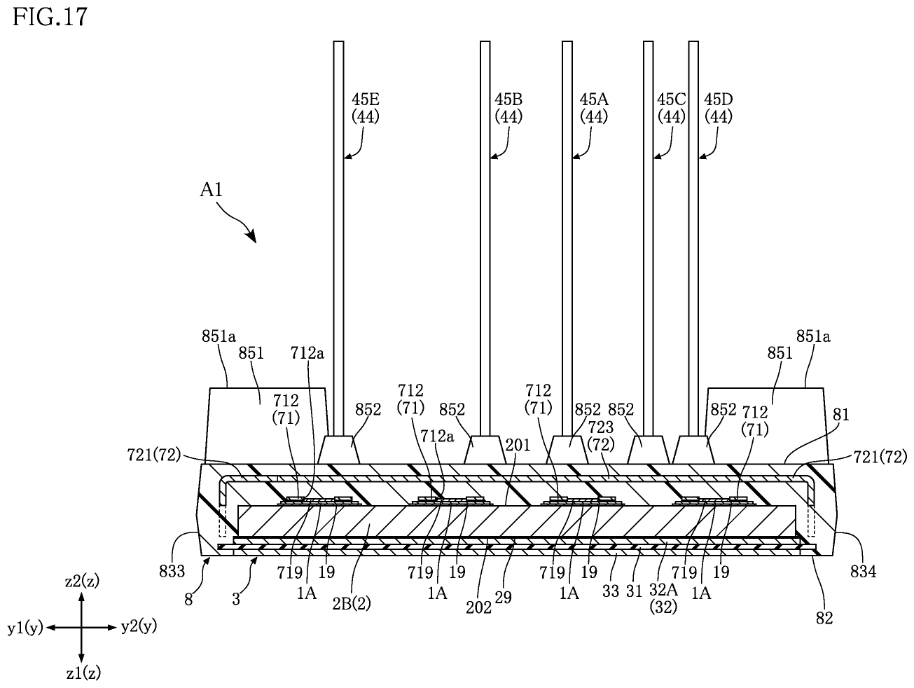

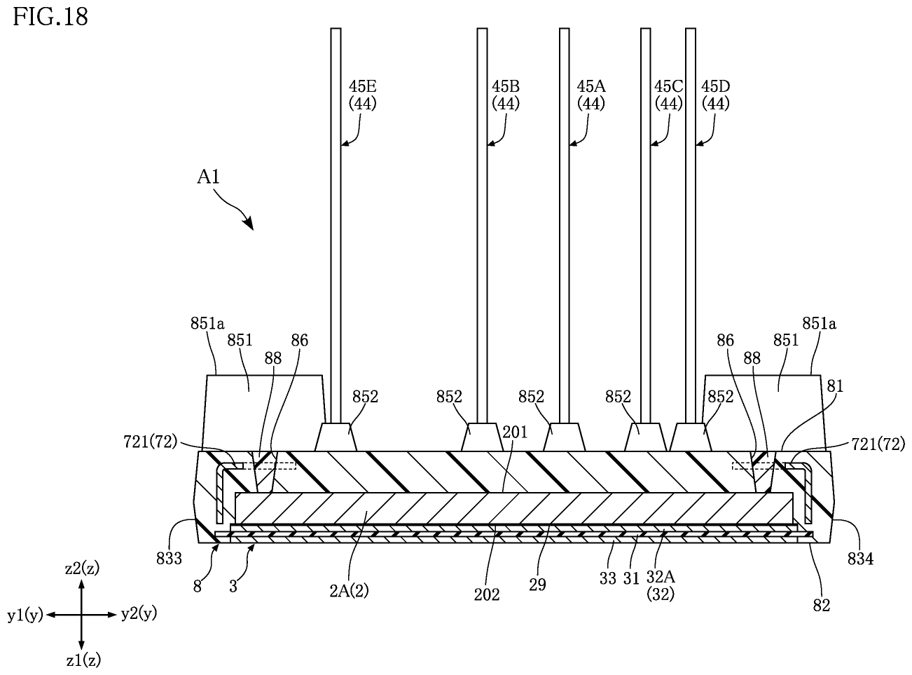

FIGS. 1 to 18 show a semiconductor device A1 according to one embodiment of the present disclosure. The semiconductor device A1 includes a plurality of semiconductor elements 1, a supporting conductor 2, a supporting substrate 3, a plurality of power terminals 41 to 43, a plurality of control terminals 44, a signal substrate 5, a bonding layer 6, a first conductive member 71, a second conductive member 72, a plurality of wires 73 to 76, a resin member 8 and a resin filled part 88. The semiconductor elements 1 include a plurality of first switching elements 1A and a plurality of second switching elements 1B. The supporting conductor 2 includes a first conductive part 2A and a second conductive part 2B. The control terminals 44 include a plurality of first control terminals 45 and a plurality of second control terminals 46. The signal substrate 5 includes a first signal substrate 5A and a second signal substrate 5B. The bonding layer 6 includes a first bonding body 6A and a second bonding body 6B.

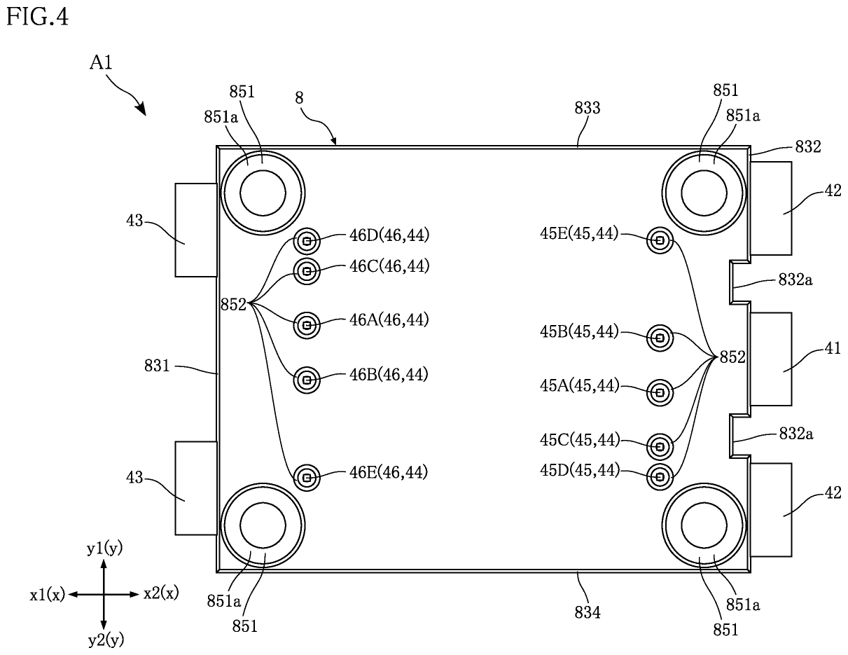

For the convenience of description, three mutually orthogonal directions are referred to as x, y and directions. In one example, the z direction is the thickness direction of the semiconductor device A1. The x direction is the horizontal direction in plan view of the semiconductor device A1 (see FIG. 4). The y direction is the vertical direction in plan view of the semiconductor device A1 (see FIG. 4). In the following description, a “plan view” refers to the view as seen in the z direction. Note that terms such as “top”, “bottom”, “upward”, “downward”, “upper surface” and “lower surface” are merely used to describe the relative positions of elements and components with respect to the z direction, and not necessarily with respect to the gravitational vertical. The x direction is an example of a “first direction”.

The semiconductor elements 1 are electronic components integral to the function of the semiconductor device A1. The semiconductor elements 1 are made of a semiconductor material, such as a material containing silicon carbide (SiC) as a main component. The semiconductor material is not limited to SiC and may be silicon (Si), gallium nitride (GaN), or diamond (C). Note that the semiconductor elements 1 are power semiconductor chips having a switching function, and metal-oxide-semiconductor field-effect transistors (MOSFETs) are one example. Although the semiconductor elements 1 in the present embodiment are MOSFETs, the semiconductor elements 1 may be other types of transistors, such as IGBTs (insulated gate bipolar transistors). All of the semiconductor elements 1 are the same type of elements. For example, the semiconductor elements 1 are n-channel MOSFETs, which may be p-channel MOSFETs in another example.

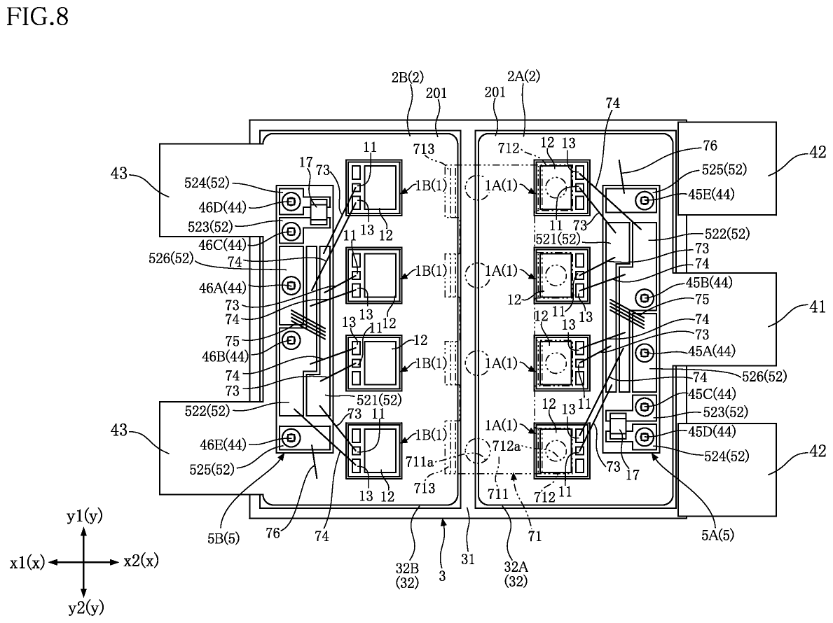

The semiconductor elements 1 include the plurality of first switching elements 1A and the plurality of second switching elements 1B. As shown in FIG. 8, the semiconductor device A1 includes four first switching elements 1A and four second switching element 1B. The numbers of the first switching elements 1A and the second switching elements 1B are not limited to four and can be changed depending on the performance desired for the semiconductor device A1. The numbers of the first switching elements 1A and the second switching elements 1B may be equal or different. The numbers of the first switching elements 1A and the second switching elements 1B are determined by the current carrying capacity of the semiconductor device A1.

In one example, the semiconductor device A1 is configured as a half-bridge switching circuit. In this case, the first switching elements 1A form the upper arm circuit, and the second switching elements 1B form the lower arm circuit. The first switching elements 1A forming the upper arm circuit are connected to each other in parallel, and the second switching elements 1B forming the lower arm circuit are connected to each other in parallel. In addition, each first switching element 1A and a relevant second switching element 1B are serially connected.

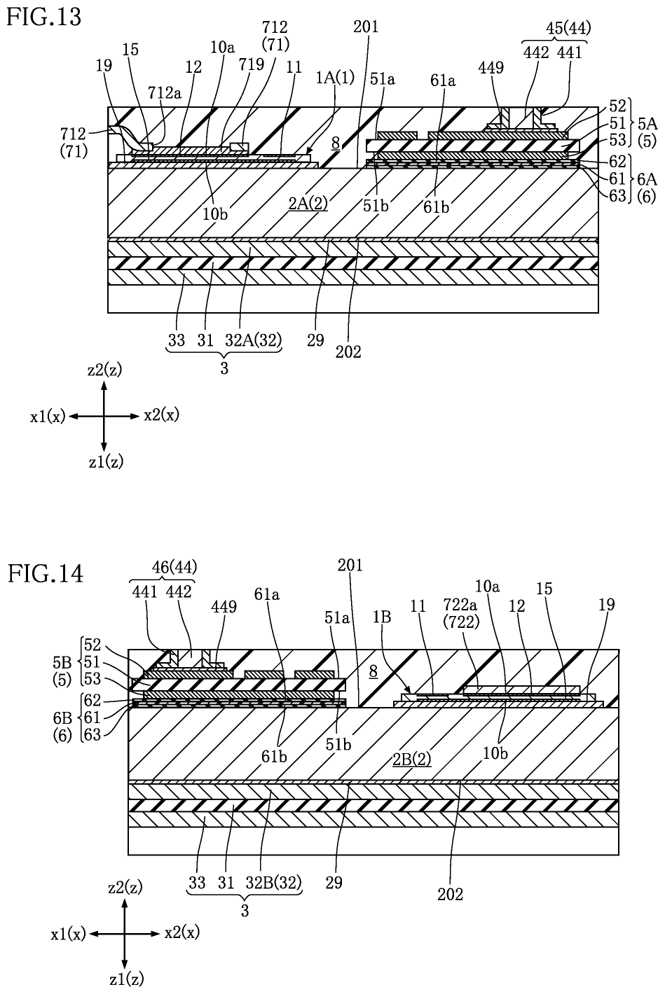

As shown in FIGS. 13 and 14, each of the semiconductor elements 1 (the first switching elements 1A and the second switching elements 1B) has an element obverse surface 10a and an element reverse surface 10b. The element obverse surface 10a and the element reverse surface 10b of each semiconductor element 1 is spaced apart in the z direction. The element obverse surface 10a faces in the z2 direction, and the element reverse surface 10b faces in the z1 direction.

As shown, for example, in FIGS. 8, 12, 13 and 17, the first switching elements 1A are mounted on the supporting conductor 2 (the first conductive part 2A). In the example shown in FIG. 8, the first switching elements 1A are aligned and spaced apart in the y direction. The first switching elements 1A are electrically bonded to the supporting conductor 2 (the first conductive part 2A) via a conductive bonding material 19. Examples of the conductive bonding material 19 include solder, a metal paste and sintered metal. Each first switching element 1A is bonded to the first conductive part 2A with the element reverse surface 10b facing the supporting conductor 2 (the first conductive part 2A).

As shown, for example, in FIGS. 8, 12, 14 and 16, the second switching elements 1B are mounted on the supporting conductor 2 (the second conductive part 2B). In the example shown in FIG. 8, the second switching elements 1B are aligned and spaced apart in the y direction. The second switching elements 1B are electrically bonded to the supporting conductor 2 (the second conductive part 2B) via the conductive bonding material 19. Each second switching element 1B is bonded to the second conductive part 2B with the element reverse surface 10b facing the supporting conductor 2 (the second conductive part 2B). As can be seen from FIG. 8, the first switching elements 1A overlap with the second switching elements 1B as viewed in the x direction. In a different example, the first switching elements 1A and the second switching elements 1B may be arranged without overlap as viewed in the x direction.

As shown in FIGS. 8, 13 and 14, each of the semiconductor elements 1 (the first switching elements 1A and the second switching elements 1B) includes a first obverse-surface electrode 11, a second obverse-surface electrode 12, a third obverse-surface electrode 13 and a reverse-surface electrode 15. The description given below of the first obverse-surface electrode 11, the second obverse-surface electrode 12, the third obverse-surface electrode 13 and the reverse-surface electrode 15 is commonly applied to all the semiconductor elements 1. The first obverse-surface electrode 11, the second obverse-surface electrode 12 and the third obverse-surface electrode 13 are disposed on the element obverse surface 10a. The first obverse-surface electrode 11, the second obverse-surface electrode 12 and the third obverse-surface electrode 13 are insulated from each other by an insulating film not shown in the figures. The reverse-surface electrode 15 is disposed on the element reverse surface 10b. The reverse-surface electrode 15 covers the entire region (or substantially the entire region) of the element reverse surface 10b. The reverse-surface electrode 15 is formed by plating with silver (Ag), for example.

In an example in which MOSFETs are used as the semiconductor elements 1, the first obverse-surface electrode 11 may be a gate electrode to which a drive signal (e.g., gate voltage) is input for driving the semiconductor element 1. Then, the second obverse-surface electrode 12 may be a source electrode through which a source current flows. The third obverse-surface electrode 13 may be a source-sensing electrode that is held at the same potential as the second obverse-surface electrode 12. That is, the third obverse-surface electrode 13 passes the same source current as the second obverse-surface electrode 12. The reverse-surface electrode 15 may be a drain electrode through which the drain current flows.

The semiconductor element 1 switches between a conducting state and a non-conducting state in response to a drive signal (gate voltage) inputted to the first obverse-surface electrode 11 (the gate electrode). This operation of the semiconductor element 1 changing between the conducting state and the non-conducting state is called a switching operation. In the conducting state, a forward current flows from the reverse-surface electrode 15 (the drain electrode) to the second obverse-surface electrode 12 (the source electrode). In the non-conducting state, no forward current flows. By the functions of the semiconductor elements 1, the semiconductor device A1 converts a first power supply voltage (e.g., direct-current voltage) into a second power supply voltage (e.g., alternating current voltage). The first power supply voltage is inputted to (applied between) the power terminal 41 and each of the two power terminals 42, and the second power supply voltage is inputted (applied) to the two power terminals 43.

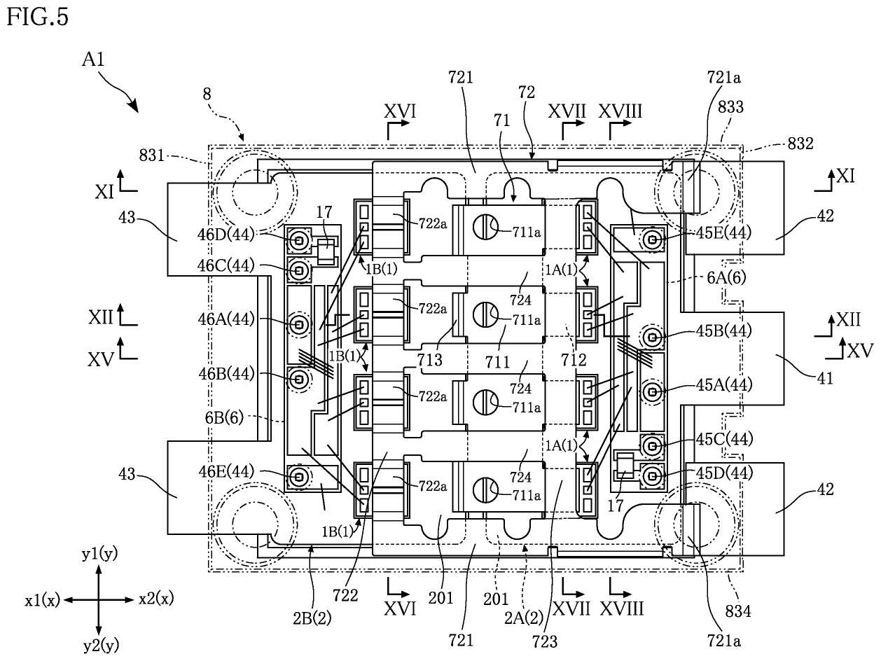

As shown, for example, in FIGS. 5 and 8, the semiconductor device A1 includes two thermistors 17. The thermistors 17 are used as temperature sensors.

The supporting conductor 2 supports the semiconductor elements 1 (the first switching elements LA and the second switching elements 1B). The supporting conductor 2 is bonded to the supporting substrate 3 via a conductive bonding material 29. Examples of the conductive bonding material 29 include solder, a metal paste and sintered metal. The supporting conductor 2 and the supporting substrate 3 may be joined together by sold-state diffusion bonding, rather than by the conductive bonding material 29. The supporting conductor 2 is rectangular in plan view, for example. The supporting conductor 2 together with the first conductive member 71 and the second conductive member 72 form paths for the main circuit current that is switched on and off by the first switching elements LA and the second switching elements 1B.

The supporting conductor 2 includes the first conductive part 2A and the second conductive part 2B. The first conductive part 2A and the second conductive part 2B are plate-like members made of metal. The metal is copper (Cu) or a Cu alloy. The first conductive part 2A and the second conductive part 2B together with the power terminals 41 to 43 form conductive paths leading to the first switching elements 1A and the second switching element 1B. For example, the first conductive part 2A and the second conductive part 2B are rectangular in plan view. For example, each of the first conductive part 2A and the second conductive part 2B has a length of at least 15 mm and at most 25 mm in the x direction, at least 30 mm and at most 40 mm in the y direction, and at least 1.0 mm and at most 5.0 mm (preferably a length of about 2.0 mm) in the z direction. These lengths of the first conductive part 2A and the second conductive part 2B are non-limiting examples and can be changed depending on the specifications of the semiconductor device A1.

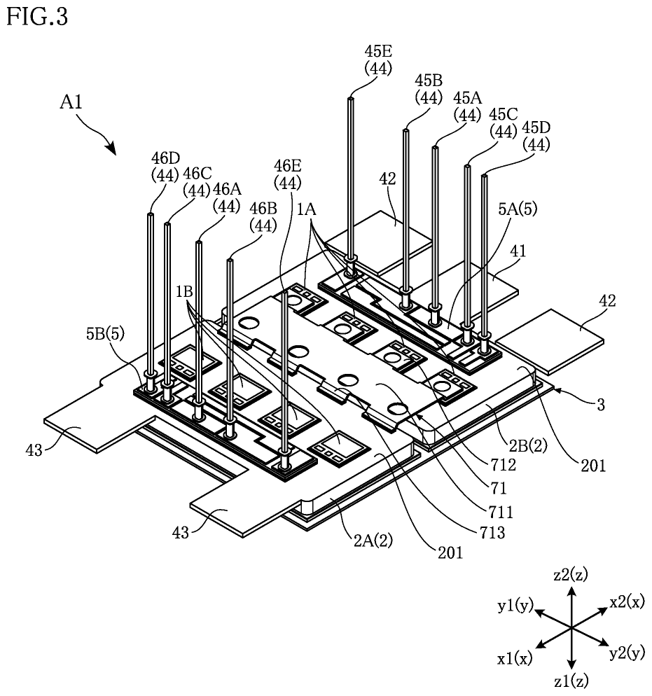

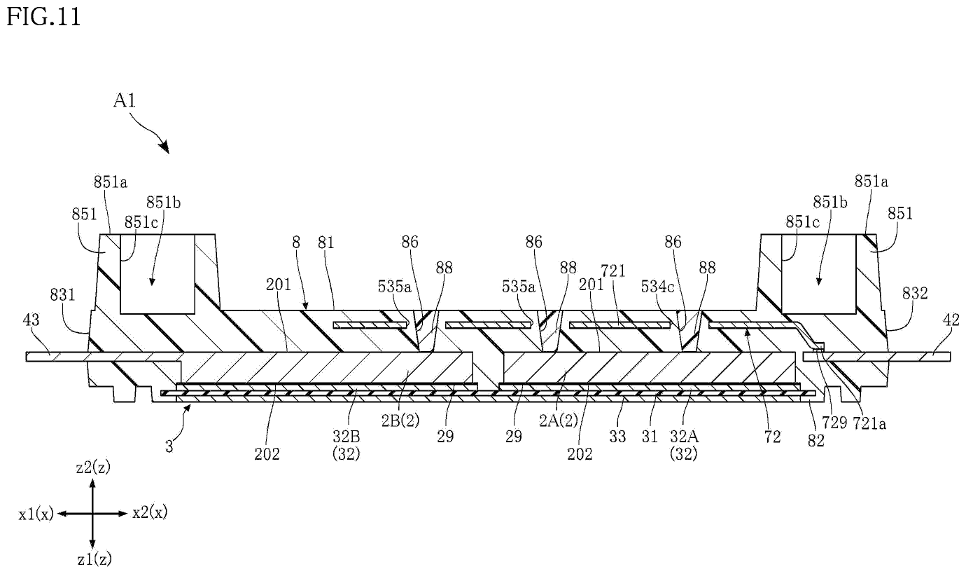

As shown in FIGS. 11 to 18, the first conductive part 2A and the second conductive part 2B are bonded to the supporting substrate 3 via the conductive bonding material 29. The first conductive part 2A has the first switching elements 1A bonded thereto via the conductive bonding material 19. The second conductive part 2B has the second switching elements 1B bonded thereto via the conductive bonding material 19. As shown in FIGS. 3, 8, 11, 12 and 15, the first conductive part 2A and the second conductive part 2B are spaced apart in the x direction. In the illustrated example, the first conductive part 2A is located in the x1 direction from the second conductive part 2B. As viewed in the x direction, the first conductive part 2A and the second conductive part 2B overlap with each other.

The supporting conductor 2 (each of the first conductive part 2A and the second conductive part 2B) has an obverse surface 201 and a reverse surface 202. As shown in FIGS. 11 to 18, the obverse surface 201 and the reverse surface 202 are spaced apart in the z direction. The obverse surface 201 faces in the z2 direction, and the reverse surface 202 in the z1 direction. The reverse surface 202 faces the supporting substrate 3.

The supporting substrate 3 supports the supporting conductor 2. The supporting substrate 3 is constructed of a direct bonded copper (DBC) substrate, for example. In a different example, the supporting substrate 3 may be constructed of a direct bonded aluminum (DBA) substrate. The supporting substrate 3 includes an insulating layer 31, a first metal layer 32 and a second metal layer 33.

The insulating layer 31 is made of a ceramic material having high thermal conductivity. Such ceramic materials include aluminum nitride (AlN), silicon nitride (SiN), aluminum oxide (Al₂O₃), and zirconia toughened alumina (ZTA). Instead of a ceramic material, the insulating layer 31 may be made of an insulating resin material. In plan view, the insulating layer 31 is rectangular, for example.

The first metal layer 32 is formed on the upper surface (the surface facing in the z2 direction) of the insulating layer 31. The first metal layer 32 is made of a material containing Cu, for example. In another example, the material of the first metal layer 32 may contain A1 (aluminum) instead of Cu. The first metal layer 32 includes a first part 32A and a second part 32B. The first part 32A and the second part 32B are spaced apart in the x direction. The first part 32A is located in the x1 direction from the second part 32B. The first part 32A is where the first conductive part 2A is bonded and supports the first conductive part 2A. The second part 32B is where the second conductive part 2B is bonded and supports the second conductive part 2B. The first part 32A and the second part 32B are rectangular in plan view, for example.

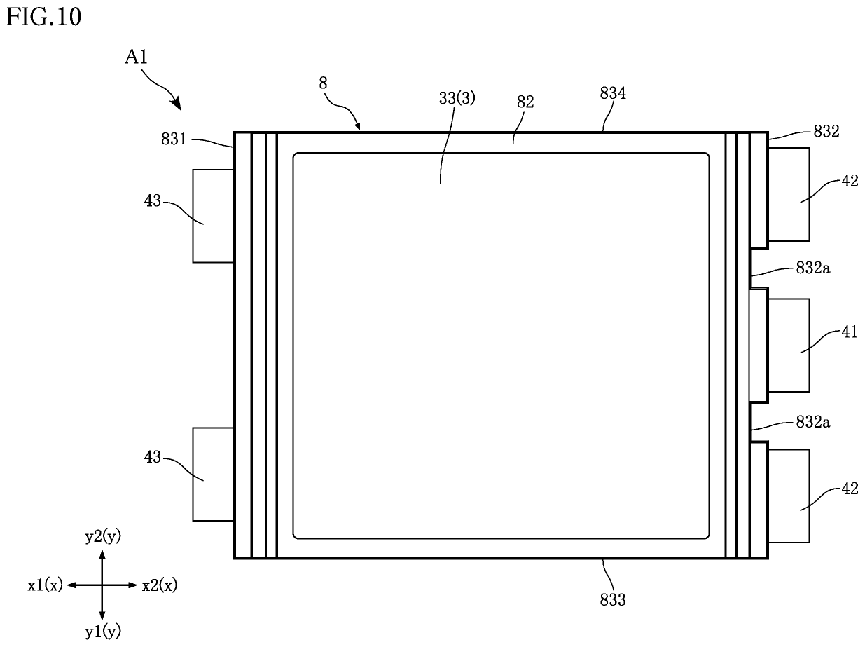

The second metal layer 33 is formed on the lower surface (the surface facing in the z1 direction) of the insulating layer 31. The second metal layer 33 is made of the same material as the first metal layer 32. As shown in FIGS. 10 to 18, the lower surface (the surface facing in the z1 direction) of the second metal layer 33 is exposed from the resin member 8. In a different example, the lower surface of the second metal layer 33 may be covered with the resin member 8. In the example in which the lower surface of the second metal layer 33 is exposed from the resin member 8, a heat-dissipating material (e.g., heat sink) may be attached to the exposed lower surface. In plan view, the second metal layer 33 overlaps with both the first part 32A and the second part 32B.

The power terminals 41 to 43 are made with metal plates. The metal plates are made of Cu or a Cu alloy, for example. In the example shown in FIGS. 1 to 5, 8 and 10, the semiconductor device A1 includes one power terminal 41, two power terminals 42 and two power terminals 43.

The first power supply voltage mentioned above is applied between the power terminal 41 and each of the two power terminals 42. The power terminal 41 is a terminal connected to the positive electrode of a DC power source (a P terminal), and each of the two power terminals 42 is a terminal connected to the negative electrode of the DC power source (an N terminal). In a different example, the power terminal 41 may be an N terminal, and the two power terminals 42 may be P terminals. In such a case, the wiring within the package are also changed according to the respective polarities of the terminals. The second power supply voltage mentioned above is applied to each of the two power terminal 43. Each power terminal 43 is an output terminal for outputting the voltage resulting from the conversion through the switching operations of the first switching elements 1A and the second switching elements 1B (the second power supply voltage mentioned above). Each of the power terminals 41 to 43 includes a portion covered with the resin member 8 and a portion exposed from the resin member 8.

As shown in FIGS. 8, 12 and 15, the power terminal 41 is formed integrally with the first conductive part 2A. In a different example, the power terminal 41 may be a separate component that is electrically bonded to the first conductive part 2A. As shown in FIG. 8, the power terminal 41 is located farther in the x2 direction than the semiconductor elements 1 and the first conductive part 2A (the supporting conductor 2). The insulating layer 31 is electrically connected to the first conductive part 2A and hence to the reverse-surface electrodes 15 (the drain electrodes) of the first switching elements 1A via the first conductive part 2A. The power terminal 41 is an example of a “first power terminal”.

As shown, for example, in FIGS. 8 and 11, both of the two power terminals 42 are spaced apart from the first conductive part 2A. To the two power terminals 42, the second conductive member 72 is bonded. As shown in FIG. 8, the two power terminals 42 are located farther in the x2 direction than the semiconductor elements 1 and the first conductive part 2A (the supporting conductor 2). The two power terminals 42 are electrically connected to the second conductive member 72, and hence to the second obverse-surface electrodes 12 (the source electrodes) of the second switching elements 1B via the second conductive member 72. Each power terminal 42 is an example of a “second power terminal”.

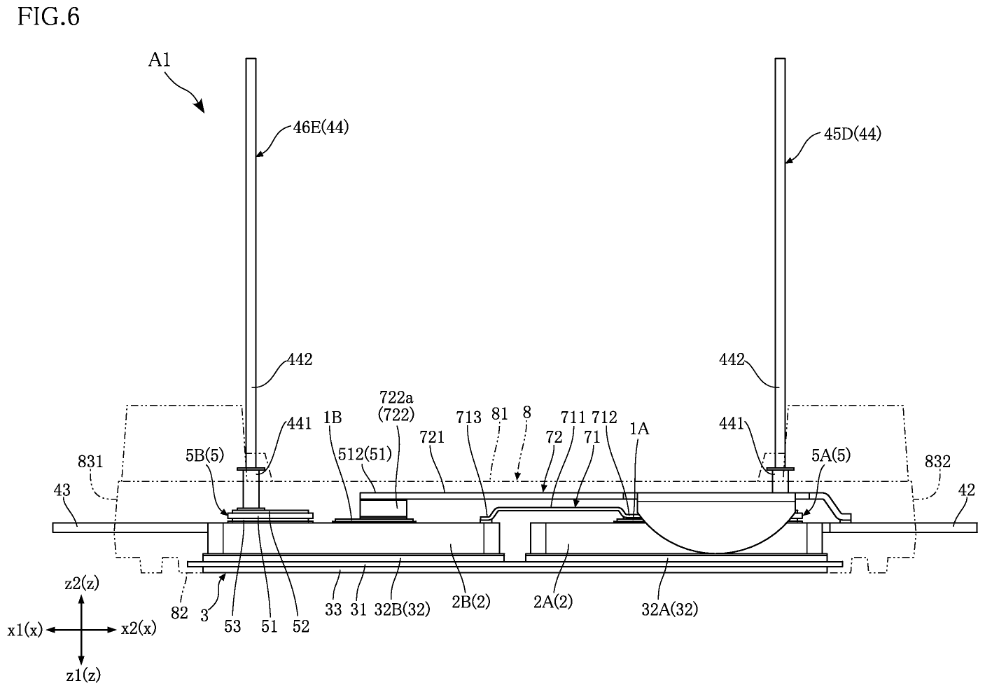

Each of the power terminals 41 and 42 protrudes from the resin member 8 in the x2 direction. The power terminals 41 and 42 are spaced apart from each other. The two power terminals 42 are located across the power terminal 41 in the y direction. As can be seen from FIGS. 6, 7 and 9, the power terminal 41 and the two power terminals 42 overlap with each other as viewed in the y direction.

As shown in FIGS. 8 and 11, the two power terminals 43 are integrally formed with the second conductive part 2B, for example. In a different example, each of the power terminals 43 may be a separate component that is electrically bonded to the second conductive part 2B. As shown in FIG. 8, the two power terminals 43 are located farther in the x1 direction than the semiconductor elements 1 and the second conductive part 2B (the supporting conductor 2). The two power terminals 43 are electrically connected to the first conductive part 2A and hence to the reverse-surface electrodes 15 (the drain electrodes) of the second switching elements 1B via the first conductive part 2A. Note that the number of power terminals 43 is not limited to two, and one or three or more power terminals 43 may be provided. When one power terminal 43 is provided, the power terminal 43 is preferably connected to the central portion of the second conductive part 2B in the y direction. Each power terminal 43 is an example of a “third power terminal”.

The control terminals 44 are pin-like terminals for controlling the drive of the semiconductor elements 1 (the first switching elements 1A and the second switching elements 1B). The control terminals 44 may be press-fit terminals, for example. Each control terminal 44 may have a length of at least 10 mm and at most 30 mm (in one example, a length of 15.8 mm) in the z direction. The length of a control terminal 44 in the z direction refers to the length from the lower end (the end in the z1 direction) of a holder 441 described later to the upper end (the end in the z2 direction) of a metal pin 442 described later. As shown in FIGS. 1 and 4, the control terminals 44 include the first control terminals 45 and the second control terminals 46. The first control terminals 45 are used to control the first switching elements 1A. The second control terminals 46 are used to control the second switching elements 1B.

As shown in FIG. 4, the first control terminals 45 are spaced apart from each other in the y direction. The first control terminals 45 are secured to the signal substrate 5 (the first signal substrate 5A). As shown in FIGS. 5 to 7 and 12, the first control terminals 45 are located between the plurality of first switching elements 1A and the plurality of power terminals 41 and 42 in the x direction. As shown in FIGS. 1 and 4, the first control terminals 45 include a first drive terminal 45A and a plurality of first sensing terminals 45B to 45E.

The first drive terminal 45A is used to input a drive signal to the first switching elements 1A (the gate terminal). A first drive signal for driving the first switching elements 1A is inputted (for example, a gate voltage is applied) to the first drive terminal 45A.

The first sensing terminal 45B is used to detect a source signal of the first switching elements 1A (the source sense terminal). The first sensing terminal 45B outputs a first detection signal that is used to detect the conducting state of the first switching elements 1A. For example, the voltage applied to the second obverse-surface electrodes 12 (the source electrodes) of the first switching elements 1A (the voltage corresponding to the source current) is detected as the first detection signal at the first sensing terminal 45B. The first sensing terminal 45C and the first sensing terminal 45D are both electrically connected to one of the two thermistors 17. This thermistor 17 is the one mounted on the first signal substrate 5A, which will be described later.

The first sensing terminal 45E is used to detect a drain signal of the first switching elements LA (the drain sense terminal). The voltage applied to the reverse-surface electrodes 15 (the drain electrodes) of the first switching elements LA (the voltage corresponding to the drain current) is detected at the first sensing terminal 45E.

As shown in FIG. 4, the second control terminals 46 are spaced apart from each other in the y direction. The second control terminals 46 are secured to the signal substrate 5 (the second signal substrate 5B). As shown in FIGS. 5 to 7 and 12, the second control terminals 46 are located between the plurality of second switching elements 1B and the plurality of power terminals 43 in the x direction. As shown in FIGS. 1 and 4, the second control terminals 46 include a second drive terminal 46A and a plurality of second sensing terminals 46B to 46E.

The second drive terminal 46A is used to input a drive signal to the second switching elements 1B (the gate terminal). A second drive signal for driving the second switching elements 1B is inputted (for example, a gate voltage is applied) to the second drive terminal 46A.

The second sensing terminal 46B is used to detect a source signal of the second switching elements 1B (the source sense terminal). The second sensing terminal 46B outputs a second detection signal that is used to detect the conducting state of the second switching elements 1B. For example, the voltage applied to the second obverse-surface electrodes 12 (the source electrodes) of the second switching elements 1B (the voltage corresponding to the source current) is detected as the second detection signal at the second sensing terminal 46B.

The second sensing terminals 46C and 46D are both electrically connected to one of the two thermistors 17. This second thermistor 17 is the one mounted on the second signal substrate 5B, which will be described later.

The second sensing terminal 46E is used to detect a drain signal of the second switching elements 1B (the drain sense terminal). The voltage applied to the reverse-surface electrodes 15 (the drain electrodes) of the second switching elements 1B (the voltage corresponding to the drain current) is detected at the second sensing terminal 46E.

Each of the control terminals 44 (the first control terminals 45 and the second control terminals 46) includes a holder 441 and a metal pin 442.

The holder 441 is made of a conductive material. As shown in FIGS. 13 and 14, the holder 441 is bonded to the signal substrate 5 (a first metal layer 52 described later) via a conductive bonding material 449. The holder 441 includes a tubular part, an upper flange and a lower flange. The upper flange extends from the upper end of the tubular part in the z direction (the end in the z2 direction), and the lower flange extends from the lower end of the tubular part in the z direction (the end in the z1 direction). The metal pin 442 is inserted into the holder 441 to extend at least from the upper flange to the tubular part. The holder 441 is embedded in the resin member 8.

The metal pin 442 is a rod-like member extending in the z direction. The metal pin 442 is press-fitted into the holder 441 and supported by the holder 441. The metal pin 442 is electrically connected to the signal substrate 5 (the first metal layer 52 described later) at least via the holder 441. As shown in FIGS. 13 and 14, the metal pin 442 inserted into the holder 441 may have the lower end (the end in the z1 direction) in contact with the conductive bonding material 449, in which case, the metal pin 442 is electrically connected to the signal substrate 5 also via the conductive bonding material 449.

The signal substrate 5 supports the control terminals 44. In the z direction, the signal substrate 5 is interposed between the supporting conductor 2 and the plurality of control terminals 44. The signal substrate 5 has a thickness (a length in the thickness direction z) of at least 0.5 mm and at most 1.0 mm, for example. The length of each control terminal 44 in the thickness direction z is at least 20 times and at most 30 times the thickness (the length in the thickness direction z) of the signal substrate 5. The signal substrate 5 includes the first signal substrate 5A and the second signal substrate 5B.

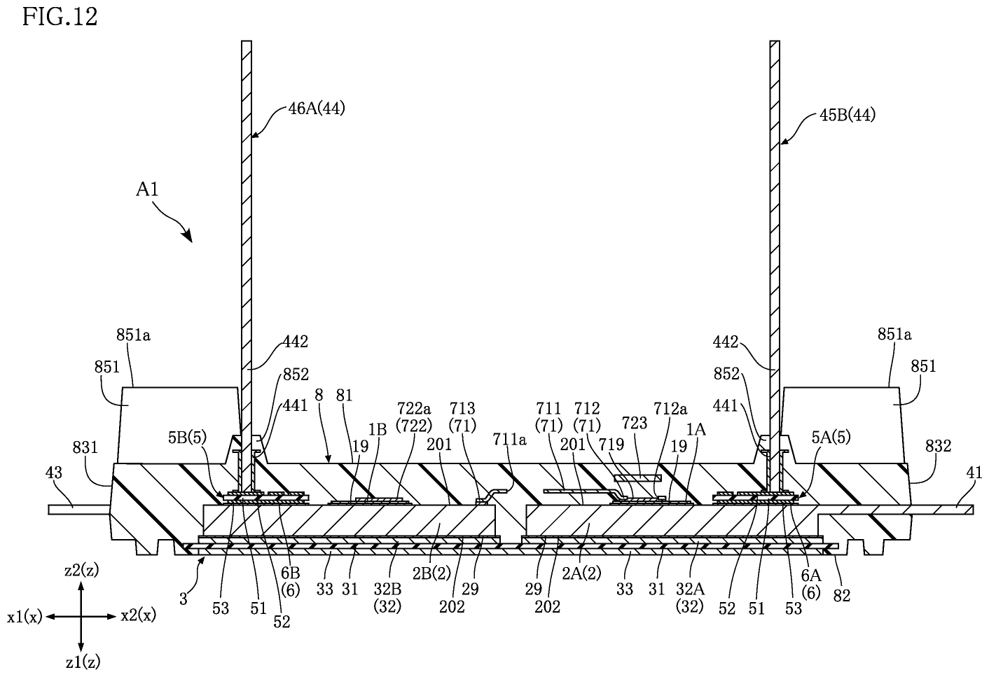

As shown in FIGS. 5, 12 and 13, the first signal substrate 5A is disposed on the first conductive part 2A and supports the first control terminals 45. As shown in FIGS. 12, 13 and 15, the first signal substrate 5A is bonded to the first conductive part 2A via the bonding layer 6 (the first bonding body 6A).

As shown in FIGS. 5, 12 and 14, the second signal substrate 5B is disposed on the second conductive part 2B and supports the second control terminals 46. As shown in FIGS. 12, 14 and 15, the second signal substrate 5B is bonded to the second conductive part 2B via the bonding layer 6 (the second bonding body 6B).

The signal substrate 5 (each of the first signal substrate 5A and the second signal substrate 5B) is constructed of a DBC substrate, for example. The signal substrate 5 is a laminate of an insulating substrate 51, a first metal layer 52 and a second metal layer 53. Unless otherwise specifically noted, the description of the insulating substrate 51, the first metal layer 52 and the second metal layer 53 given below commonly applies to the first signal substrate 5A and the second signal substrate 5B.

The insulating substrate 51 is made of a ceramic material, for example. Suitable ceramic materials include AlN, SiN and Al₂O₃. The insulating substrate 51 may be rectangular in plan view. As shown in FIGS. 13 and 14, the insulating substrate 51 has an obverse surface 51a and a reverse surface 51b. The obverse surface 51a and the reverse surface 51b are spaced apart in the z direction. The obverse surface 51a faces in the z2 direction, and the reverse surface 51b faces in the z1 direction. The reverse surface 51b faces the supporting conductor 2.

As shown in FIGS. 13 and 14, the second metal layer 53 is formed on the reverse surface 51b of the insulating substrate 51. The second metal layer 53 is bonded to the supporting conductor 2 via the bonding layer 6. The second metal layer 53 of the first signal substrate 5A is bonded to the first conductive part 2A via the first bonding body 6A described later. The second metal layer 53 of the second signal substrate 5B is bonded to the second conductive part 2B via the second bonding body 6B. The second metal layer 53 is made of Cu or a Cu alloy, for example. The second metal layer 53 is an example of a “metal layer”.

As shown in FIGS. 13 and 14, the first metal layer 52 is formed on the obverse surface 51a of the insulating substrate 51. Each control terminal 44 is disposed to stand on the first metal layer 52. The first control terminals 45 are disposed to stand on the first metal layer 52 of the first signal substrate 5A, and the second control terminals 46 are disposed to stand on the first metal layer 52 of the second signal substrate 5B. The first metal layer 52 is made of Cu or a Cu alloy, for example. As shown in FIG. 8, the first metal layer 52 includes a plurality of wiring layers 521 to 526. The wiring layers 521 to 526 are spaced apart and insulated from each other.

As shown in FIG. 8, a plurality of wires 73 are bonded to the wiring layer 521, each wire 73 electrically connecting the wiring layer 521 to the first obverse-surface electrode 11 (the gate electrode) of a semiconductor element 1. The wiring layer 521 of the first signal substrate 5A is electrically connected to the first obverse-surface electrodes 11 of the first switching element 1A via the relevant wires 73. The wiring layer 521 of the second signal substrate 5B is electrically connected to the first obverse-surface electrodes 11 of the second switching elements 1B via the relevant wires 73.

As shown in FIG. 8, a plurality of wires 75 are bonded to the wiring layer 526, each wire 75 electrically connecting the wiring layer 526 to the wiring layer 521. The wiring layer 526 of the first signal substrate 5A is electrically connected to the first obverse-surface electrodes 11 (the gate electrodes) of the first switching elements 1A via the relevant wires 75, the wiring layer 521 of the first signal substrate 5A and the relevant wires 73. The wiring layer 526 of the second signal substrate 5B is electrically connected to the first obverse-surface electrodes 11 (the gate electrodes) of the second switching elements 1B via the relevant wires 75, the wiring layer 521 of the second signal substrate 5B and the relevant wires 73. The first drive terminal 45A is bonded to the wiring layer 526 of the first signal substrate 5A, and the second drive terminal 46A is to the wiring layer 526 of the second signal substrate 5B.

As shown in FIG. 8, a plurality of wires 74 are bonded to the wiring layer 522, each wire 74 electrically connecting the wiring layer 522 to the third obverse-surface electrode 13 (the source-sense electrode) of a semiconductor element 1. The wiring layer 522 of the first signal substrate 5A is electrically connected to the third obverse-surface electrodes 13 (the source-sense electrodes) of the first switching elements 1A via the relevant wires 74. The wiring layer 522 of the second signal substrate 5B is electrically connected to the third obverse-surface electrodes 13 (the source-sense electrodes) of the second switching elements 1B via the relevant wires 74. The first sensing terminal 45B is bonded to the wiring layer 522 of the first signal substrate 5A, and the second sensing terminal 46B is bonded to the wiring layer 522 of the second signal substrate 5B.

As shown in FIG. 8, the thermistors 17 are bonded to the wiring layers 523 and 524. As shown in FIG. 8, the first sensing terminals 45C and 45D are bonded respectively to the wiring layers 523 and 524 of the first signal substrate 5A. The second sensing terminals 46C and 46D are bonded respectively to the wiring layers 523 and 524 of the second signal substrate 5B.

A wire 76 is bonded to the wiring layer 525, the wire 76 electrically connecting the wiring layer 525 to the supporting conductor 2. As shown in FIG. 8, the wiring layer 525 of the first signal substrate 5A is electrically connected to the first conductive part 2A via the relevant wire 76. The wiring layer 525 of the second signal substrate 5B is electrically connected to the second conductive part 2B via the relevant wire 76. The first sensing terminal 45E is bonded to the wiring layer 525 of the first signal substrate 5A. The second sensing terminal 46E is bonded to the wiring layer 525 of the second signal substrate 5B.

The signal substrate 5 is not limited to a DBC substrate and may be a printed board, such as a glass epoxy board, instead. The printed board includes at least the wiring layers 521 to 526.

The bonding layer 6 bonds the signal substrate 5 and the supporting conductor 2. In the z direction, the bonding layer 6 is interposed between the signal substrate 5 and the supporting conductor 2. The bonding layer 6 overlaps with the signal substrate 5 in plan view. The bonding layer 6 has a thickness (a length in the z direction) of at least 20 μm and at most 200 μm (in one example, a thickness of 85 μm).

As shown in FIGS. 12 to 14, the bonding layer 6 includes the first bonding body 6A and the second bonding body 6B. The first bonding body 6A bonds the first signal substrate 5A and the first conductive part 2A. The first bonding body 6A is interposed between the first signal substrate 5A and the first conductive part 2A, and overlaps with the first signal substrate 5A in plan view. The second bonding body 6B bonds the second signal substrate 5B and the second conductive part 2B. The second bonding body 6B is interposed between the second signal substrate 5B and the second conductive part 2B, and overlaps with the second signal substrate 5B in plan view.

As shown in FIGS. 13 and 14, the bonding layer 6 (each of the first bonding body 6A and the second bonding body 6B) includes an insulating layer 61 and a pair of adhesive layers 62 and 63. Unless otherwise specifically noted, the description of the insulating layer 61 and the adhesive layers 62 and 63 given below commonly applies to the first bonding body 6A and the second bonding body 6B.

The insulating layer 61 is made of a resin material. In view of the heat resistance and electrical insulation, polyimide is a desirable example of the resin material. The insulating layer 61 of the first bonding body 6A electrically insulates the first signal substrate 5A and the first conductive part 2A. Similarly, the insulating layer 61 of the second bonding body 6B electrically insulates the second signal substrate 5B and the second conductive part 2B. In one example, the insulating layer 61 is in the form of a film. In another example, the insulating layer 61 may be in the form of a sheet or a plate. In the present disclosure, the sheet refers to a piece of material that is as flexible as the film but thicker than the film. Also, the plate refers to a piece of material that is harder and less flexible than the film or the sheet and thicker than the sheet. The definitions of the film, sheet and plate are not limited to those described above and may be adapted according to common classifications. The insulating layer 61 has a thickness (a length in the thickness direction z) that is at least 0.1% and at most 1.0% of the length of each control terminal 44 in the thickness direction z. The insulating layer 61 has a thickness (a length in the thickness direction z) that is at least 20% and at most 75% of the thickness (the length in the thickness direction z) of the bonding layer 6. Specifically, the thickness (the length in the thickness direction z) of the insulating layer 61 is at least 10 μm and at most 150 μm (in one example, the thickness is 25 μm).

As shown in FIGS. 13 and 14, the insulating layer 61 has an obverse surface 61a and a reverse surface 61b. The obverse surface 61a and the reverse surface 61b are spaced apart in the z direction. The obverse surface 61a faces in the z2 direction (upward in the z direction), and the reverse surface 61b faces in the z1 direction (downward in the z direction).

The adhesive layers 62 and 63 are disposed on the opposite sides of the insulating layer 61 in the z direction. The adhesive layers 62 and 63 are made of a silicone-based adhesive or an acrylic-based adhesive, for example. Each of the adhesive layers 62 and 63 has a thickness (a length in the thickness direction z) that is at least 10% and at most 150% of the thickness (the length in the thickness direction z) of the insulating layer 61. Specifically, the thickness (the length in the thickness direction z) of the adhesive layers 62 and 63 is at least 5 μm and at most 50 μm (in one example, the thickness is 30 μm).

As shown in FIGS. 13 and 14, the adhesive layer 62 is formed on the obverse surface 61a. In the z direction, the adhesive layer 62 is interposed between the insulating layer 61 and the signal substrate 5. The adhesive layer 62 of the first bonding body 6A is interposed between the insulating layer 61 of the first bonding body 6A and the first signal substrate 5A in the z direction. The adhesive layer 62 of the second bonding body 6B is located between the insulating layer 61 of the second bonding body 6B and the second signal substrate 5B in the z direction.

As shown in FIGS. 13 and 14, the adhesive layer 63 is formed on the reverse surface 61b. In the z direction, the adhesive layer 63 is interposed between the insulating layer 61 and the supporting conductor 2. The adhesive layer 63 of the first bonding body 6A is interposed between the insulating layer 61 of the first bonding body 6A and the first conductive part 2A in the z direction. The adhesive layer 63 of the second bonding body 6B is interposed between the insulating layer 61 of the second bonding body 6B and the second conductive part 2B in the z direction.

As can be understood from the above description, the bonding layer 6 of the present disclosure is a kind of double sided adhesive tape. In a process of manufacturing the semiconductor device A1, the bonding layer 6 may be attached first to the signal substrate 5 to which the control terminals 44 have been bonded, and then to the supporting conductor 2. The bonding layer 6 is not limited to a double sided adhesive tape, but a material that is melted to bond two members together, such as solder, is excluded. In other words, the bonding layer 6 is a material capable of bonding two members together without being melted.

The first conductive member 71 and the second conductive member 72 together with the supporting conductor 2 form paths for the main circuit current that is switched on and off by the semiconductor elements 1 (the first switching elements LA and the second switching elements 1B). Each of the first conductive member 71 and the second conductive member 72 is spaced apart from the respective obverse surfaces 201 of the first conductive part 2A and the second conductive part 2B in the z2 direction, and overlaps with the respective obverse surfaces 201 in plan view. The first conductive member 71 and the second conductive member 72 are constructed of metal plates, for example. The metal is copper or a Cu alloy, for example. The first conductive member 71 and the second conductive member 72 has been bent as necessary.

The first conductive member 71 electrically connects the first switching elements 1A and the second conductive part 2B. As shown in FIGS. 5 and 8, the first conductive member 71 is connected to the second obverse-surface electrode 12 (the source electrode) of each first switching elements 1A and also to the second conductive part 2B, thereby electrically connecting the second obverse-surface electrodes 12 of the first switching elements 1A and the second conductive part 2B. The first conductive member 71 forms paths for the main circuit current that is switched on and off by the first switching elements 1A. As shown in FIGS. 5, 8 and 12, the first conductive member 71 includes a main part 711, a plurality of first connecting ends 712 and a plurality of second connecting ends 713.

The main part 711 is located between the plurality of first switching elements 1A and the second conductive part 2B. The main part 711 has a band shape extending in the y direction. As shown in FIG. 12, the main part 711 is located farther in the z2 direction than the first connecting ends 712 and the second connecting ends 713. As shown in FIGS. 5, 8 and 12, in the present embodiment, the main part 711 is formed with a plurality of openings 711a. Each opening 711a is a through-hole penetrating the first conductive member 71 (the main part 711) in the z direction. The openings 711a are aligned at intervals in the y direction. In plan view, the openings 711a do not overlap with the second conductive member 72. The openings 711a are provided for improving the flow of a melted resin material injected in the process of forming the resin member 8. That is, the openings 711a allow the flow of the resin material between the upper region (in the z2 direction) and the lower region (in the z1 direction) around the main part 711 (the first conductive member 71). The shape of main part 711 is not limited to this configuration and may be formed without any opening 711a.

The first connecting ends 712 and the second connecting ends 713 are connected to the main part 711, and each of first connecting ends 712 and the second connecting ends 713 is located at a position opposite a first switching element 1A. As shown in FIG. 12, the first connecting ends 712 are bonded to the second obverse-surface electrodes 12 of the first switching elements 1A via a conductive bonding material 719. The second connecting ends 713 are bonded to the second conductive part 2B via the conductive bonding material 719. Examples of the conductive bonding material 719 include solder, a metal paste and sintered metal. In the example shown in FIGS. 8, 12, 13 and 17, each first connecting end 712 is formed with an opening 712a. Preferably, each opening 712a is formed to overlap the central portion of the relevant first switching element 1A in plan view. As shown in FIGS. 12, 13 and 17, each opening 712a is a through-hole penetrating the relevant first connecting end 712 in the z direction. The openings 712a are used for positioning the first conductive member 71 relative to the supporting conductor 2.

In the illustrated example, the main part 711 connects the first connecting ends 712 and the second connecting ends 713. In another example, the main part 711 may be composed of a plurality of separate portions each connecting a first connecting end 712 and a second connecting ends 713. In other words, a separate first conductive member 71 may be provided for each first switching element 1A.

As shown in FIG. 5, the second conductive member 72 is connected to the second obverse-surface electrodes 12 (the source electrodes) of the second switching elements 1B and the power terminals 42, thereby electrically connecting the second obverse-surface electrodes 12 of the second switching elements 1B to the power terminals 42. The second conductive member 72 forms paths for the main circuit current that is switched on and off by the second switching elements 1B. The second conductive member 72 has a maximum length of at least 25 mm and at most 40 mm in the x direction and a maximum length of at least 30 mm and at most 45 mm in the y direction. As shown in FIG. 5, the second conductive member 72 includes a pair of first wiring parts 721, a second wiring part 722, a third wiring part 723 and a fourth wiring part 724.

One of the first wiring parts 721 is connected to one of the power terminals 42, and the other first wiring part 721 is connected to the other power terminal 42. As shown in FIG. 5, each first wiring part 721 has a band shape extending in the x direction. The first wiring parts 721 are spaced apart in the y direction and parallel (or substantially parallel) to each other. As shown in FIGS. 5 and 11, each first wiring part 721 includes a first end 721a. The first end 721a is the end of the first wiring part 721 in the x2 direction. As shown in FIG. 11, the first end 721a is located farther in the z1 direction than the rest of the first wiring part 721. As shown in FIG. 11, each first end 721a is bonded to one of the power terminals 42 via a conductive bonding material 729. Examples of the conductive bonding material 729 include solder, a metal paste and sintered metal. In the example shown in FIG. 5, each first wiring part 721 is formed with a plurality of notches. The notches formed in the first wiring part 721 are semicircular in plan view and overlap with the supporting conductor 2 in plan view.

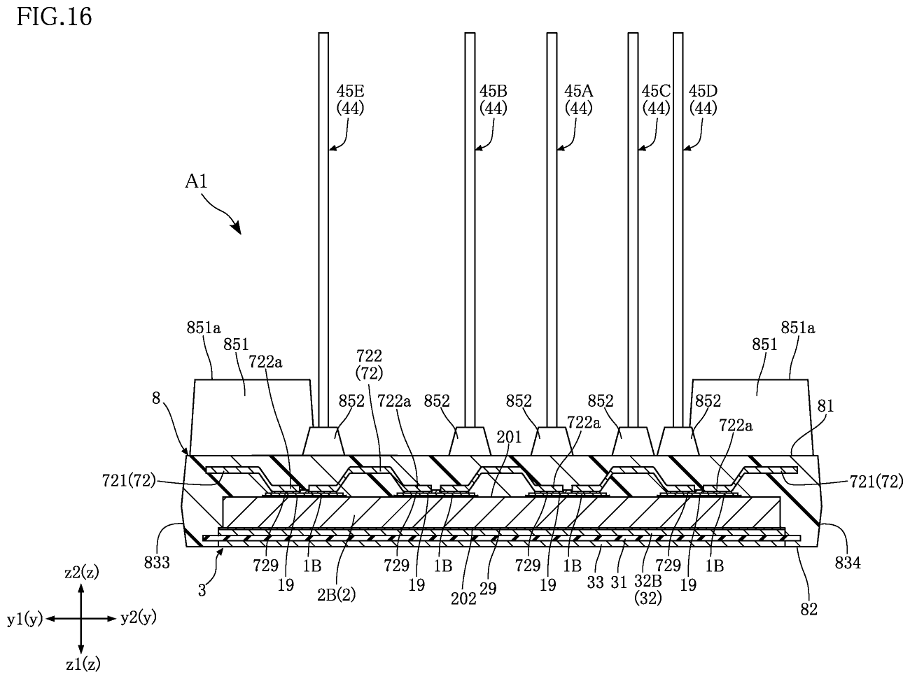

As shown in FIG. 5, the second wiring part 722 is connected to both of the first wiring parts 721. The second wiring part 722 is located between the first wiring parts 721 in the y direction. In plan view, the second wiring part 722 has a band shape extending in the y direction. As shown in FIG. 5, the second wiring part 722 overlaps with the second switching elements 1B. The second wiring part 722 is connected to the second switching elements 1B. The second wiring part 722 has a plurality of recessed regions 722a. As shown in FIG. 16, each recessed region 722a is recessed downward in the z direction (in the z1 direction) from the rest of the second wiring part 722. As shown in FIG. 16, the recessed regions 722a of the second wiring part 722 are bonded to the second obverse-surface electrodes 12 (the source electrodes) of the second switching elements 1B via a conductive bonding material 729. In the example shown in FIGS. 5 and 16, each recessed region 722a has a slit. The slit extends in the x direction at the center of the recessed region 722a in the y direction. That is, each recessed region 722a is composed of two sections that are spaced apart in the y direction across the slit. In another example, each recessed region 722a may be without a slit.

As shown in FIG. 5, the third wiring part 723 is connected to both of the first wiring parts 721. The third wiring part 723 is located between the first wiring parts 721 in the y direction. In plan view, the third wiring part 723 has a band shape extending in the y direction. The third wiring part 723 is spaced apart from the second wiring part 722 in the x direction. The third wiring part 723 is arranged parallel (or substantially parallel) to the second wiring part 722. As shown in FIG. 5, the third wiring part 723 overlaps with the first switching elements 1A in plan view. In the z direction, the third wiring part 723 is located above (in the z2 direction from) the first connecting ends 712 of the first conductive member 71. In plan view, the third wiring part 723 overlaps with the first connecting end 712.

As shown in FIG. 5, each fourth wiring part 724 is connected to both the second wiring part 722 and the third wiring part 723. The fourth wiring parts 724 are located between the second wiring part 722 and the third wiring part 723 in the x direction. In plan view, the fourth wiring parts 724 have a band shape extending in the x direction. The fourth wiring parts 724 are spaced apart in the y direction and are arranged parallel (or substantially parallel) to each other in plan view. The fourth wiring parts 724 are also parallel (or substantially parallel) to the first wiring parts 721. One end of each fourth wiring part 724 in the x direction is connected to a portion of the third wiring part 723 that is located between two adjacent first switching elements 1A in the y direction in plan view. The other end of each fourth wiring part 724 in the x direction is connected to a portion of the second wiring part 722 that is located between two adjacent second switching elements 1B in the y direction in plan view. In one example, the fourth wiring parts 724 overlap with the first conductive member 71 (the main part 711).

The wires 73 to 76 are bonding wires, for example, and electrically connect two separate parts. The wires 73 to 76 are made of a material containing gold (Au), A1 or Cu.

Each wire 73 is bonded to the wiring layer 521 and the first obverse-surface electrode 11 (the gate electrode) of a semiconductor element 1 to provide an electrical connection between them. As shown in FIG. 8, the wires 73 include those bonded to the wiring layer 521 of the first signal substrate 5A and the first obverse-surface electrodes 11 of the first switching elements 1A, and those bonded to the wiring layer 521 of the second signal substrate 5B and the first obverse-surface electrodes 11 of the second switching elements 1B.

Each wire 74 is bonded to the wiring layer 522 and the third obverse-surface electrode 13 (the source-sensing electrode) of a semiconductor element 1 to provide an electrical connection between them. As shown in FIG. 8, the wires 74 include those bonded to the wiring layer 522 of the first signal substrate 5A and the third obverse-surface electrodes 13 of the first switching elements 1A, and those bonded to the wiring layer 522 of the second signal substrate 5B and the third obverse-surface electrodes 13 of the second switching elements 1B. In some configuration, the semiconductor elements 1 are not provided with the third obverse-surface electrodes 13, in which case, each wire 74 is bonded to the second obverse-surface electrode 12 instead of the third obverse-surface electrode 13.

The wires 75 are bonded to the wiring layer 521 and the wiring layer 526 to provide an electrical connection between them. As shown in FIG. 8, the wires 75 include those bonded to the wiring layer 521 of the first signal substrate 5A and the wiring layer 526 of the first signal substrate 5A and those bonded to the wiring layer 521 of the second signal substrate 5B and the wiring layer 526 of the second signal substrate 5B.

The wires 76 are bonded to the wiring layer 525 and the supporting conductor 2 to provide an electrical connection between them. As shown in FIG. 8, the wires 76 include one bonded to the wiring layer 525 of the first signal substrate 5A and the first conductive part 2A and one bonded to the wiring layer 525 of the second signal substrate 5B and the second conductive part 2B.

The resin member 8 is a sealing material for protecting the semiconductor elements 1 (the first switching elements 1A and the second switching elements 1B). The resin member 8 covers the semiconductor elements 1 (the first switching elements 1A and the second switching elements 1B), the supporting conductor 2 (the first conductive part 2A and the second conductive part 2B), the supporting substrate 3 (except at the lower surface of the second metal layer 33), a portion of each of the power terminals 41 to 43, a portion of each control terminal 44, the signal substrate 5 (the first signal substrate 5A and the second signal substrate 5B), the bonding layer 6 (the first bonding body 6A and the second bonding body 6B), the first conductive member 71, the second conductive member 72 and the wires 73 to 76. The resin member 8 is made of a black epoxy resin, for example. The resin member 8 is formed by molding, for example. The resin member 8 has a length of about 35 to 60 mm in the x direction, about 35 to 50 mm in the y direction, and about 4 to 15 mm in the z direction, for example. These lengths are measured at the largest portions in the respective directions. The resin member 8 has a resin obverse surface 81, a resin reverse surface 82 and resin side surfaces 831 to 834.

As shown in FIGS. 6, 7, 9, 11, 12 and 15 to 18, the resin obverse surface 81 and the resin reverse surface 82 are spaced apart in the z direction. The resin obverse surface 81 faces in the z2 direction, and the reverse surface 82 faces in the z1 direction. The control terminals 44 (the first control terminals 45 and the second control terminals 46) protrude from the resin obverse surface 81. In plan view as shown in FIG. 10, the resin reverse surface 82 has the shape of a frame surrounding the lower surface of the second metal layer 33 of the supporting substrate 3. The lower surface of the second metal layer 33 is exposed on the resin reverse surface 82. In one example, the second metal layer 33 is flush with the resin reverse surface 82. Each of the resin side surfaces 831 to 834 is connected to both the resin obverse surface 81 and the resin reverse surface 82 and located between them in the z direction. As shown in FIG. 4, for example, the resin side surfaces 831 and 832 are spaced apart in the x direction. The resin side surface 831 faces in the x1 direction, and the resin side surface 832 faces in the x2 direction. The two power terminals 43 protrude from the resin side surface 831, and the power terminals 41 and 42 protrude from the resin side surface 832. As shown, for example, in FIG. 4, the resin side surfaces 833 and 834 are spaced apart in the y direction. The resin side surface 833 faces in the y1 direction, and the resin side surface 834 faces in the y2 direction.

The resin side surface 832 is formed with a plurality of recesses 832a as shown in FIG. 4. In plan view, each recess 832a is recessed in the x direction. One of the recesses 832a is formed between the power terminal 41 and one of the power terminals 42, another one is formed between the power terminal 41 and the other power terminal 42. Each recess 832a is provided to increase the creepage distance along the resin side surfaces 832 between the power terminal 41 and the relevant power terminal 42.

As shown in FIGS. 11 and 12, for example, the resin member 8 has a plurality of first projections 851, a plurality of second projections 852 and a resin cavity 86.

The first projections 851 protrude from the resin obverse surface 81 in the z direction. In plan view, the first projections 851 are located at or near the four corners of the resin member 8. Each first projection 851 has a first-projection end surface 851a at its end (the end in the z2 direction). The first-projection end surfaces 851a of the first projections 851 are parallel (or substantially parallel) to the resin obverse surface 81. The first-projection end surfaces 851a lie in the same plane (x-y plane). Each first projection 851 has the shape of a truncated hollow cone with a bottom, for example. The first projections 851 serve as spacers when the semiconductor device A1 is mounted on, for example, a control circuit board. The control circuit board is a part of a device that will use the power generated by the semiconductor device A1. As shown in FIG. 11, each first projection 851 has a recess 851b and an inner wall 851c defining the recess 851b. Each first projection 851 is a columnar structure, which preferably is a cylindrical column. Preferably, the recess 851b has a cylindrical shape and the inner wall 851c defines one perfect circle in plan view.

The semiconductor device A1 may be fastened to the control circuit board or the like by one or more screws, for example. For this purpose, each first projection 851 may be provided with an internal thread on the inner wall 851c of the recess 832a. For example, an insert nut may be inserted into the recess 832a of each first projection 851.

As shown, for example, in FIG. 12, the second projections 852 protrude from the resin obverse surface 81 in the z direction. In plan view, the second projections 852 overlap with the control terminals 44. The metal pin 442 of each control terminal 44 protrudes from a second projection 852. Each second projection 852 has the shape of a truncated cone. Each second projection 852 covers the holder 441 and a portion of the metal pin 442 of the relevant control terminal 44.

As shown in FIG. 11, each resin cavity 86 extends in the z direction from the resin obverse surface 81 to the obverse surface 201 of the first conductive part 2A or the second conductive part 2B. Each resin cavity 86 is tapered from the resin obverse surface 81 to the obverse surface 201, so that the cross section orthogonal to the z direction is gradually smaller. The resin cavities 86 are holes in the resin member 8 and formed at the time of molding the resin member 8.

The resin cavities 86 may be formed as a result that the spaces occupied by pressing members during the molding of the resin member are left unfilled with a melted resin material injected to form the resin member 8. The pressing members, which are used to apply pressing force to the obverse surface 201 at the time of the molding, are inserted into the notches formed in the first wiring parts 721 of the second conductive member 72. In this way, the pressing members can press the supporting conductor 2 (the first conductive part 2A and the second conductive part 2B), without interfering with the second conductive member 72. This can prevent warping of the supporting substrate 3 to which the supporting conductor 2 is bonded.

As shown in FIG. 11, the semiconductor device A1 of the present embodiment includes the resin filled parts 88. The resin filled parts 88 are formed by filling the resin cavities 86 with a resin material. The resin material forming the resin filled part 88 may be the same epoxy resin as that forming the resin member 8 or a resin material different from that forming the resin member 8.

Advantages of the semiconductor device A1 are as follows.

The semiconductor device A1 includes the control terminals 44, the signal substrate 5 including the wiring layers 521 to 526, the supporting conductor 2 and the bonding layer 6. The control terminals 44 are secured to the wiring layers 521 to 526. The supporting conductor 2 supports the wiring layers 521 to 526 via the insulating substrate 51. The bonding layer 6 is interposed between the supporting conductor 2 and the signal substrate 5. The bonding layer 6 includes the insulating layer 61 that electrically insulates the supporting conductor 2 and the signal substrate 5. In this configuration, the signal substrate 5 is supported by the supporting conductor 2 via the bonding layer 6. In a different configuration, solder may be used instead of the bonding layer 6 and placed between the signal substrate 5 and the supporting conductor 2. In this case, the signal substrate 5 is supported by the supporting conductor 2 via a solder layer. Notably, solder is melted in the bonding process, and thus the thickness (the length in the z direction) of a solder layer is difficult to control and can be nonuniform. As a result, the signal substrate 5 may be mounted in a tilted position relative to the supporting conductor 2. In contrast, the semiconductor device A1 is provided with the bonding layer 6 between the signal substrate and the supporting conductor 2. The use of the bonding layer 6 instead of a solder layer can reduce the thickness variation described above. This can prevent the tilt of the signal substrate 5 relative to the supporting conductor 2. This can consequently prevent the tilt of the wiring layers 521 to 526, to which the control terminals 44 are secured, relative to the supporting conductor 2. The semiconductor device A1 can therefore reduce bonding failure and positional deviation of the control terminals 44, thereby improving the reliability.

In the semiconductor device A1, each control terminal 44 includes a holder 441 and a metal pin 442. The holders 441 are bonded to the first metal layer 52 (the wiring layers 521 to 526) of the signal substrate 5, and the metal pins 442 extend in the z direction. That is, the control terminals 44 are pin terminals extending in the z direction. With this configuration, when the signal substrate 5 is tilted at an angle relative to the supporting conductor 2, the tip of each metal pin 442 is tilted at a greater angle relative to the supporting conductor 2. The tilt at the tip of each metal pins 442 becomes more significant when the length of the control terminals 44 in the thickness direction z is 20 times or more the length of signal substrate 5 in the thickness direction z. It is therefore desirable to place the signal substrate 5 more accurately parallel to the supporting conductor 2. As such, using the bonding layer 6 to bond (attach) the signal substrate 5 to the supporting conductor 2 is effective for reducing the tilt of the wiring layers 521 to 526 relative to the supporting conductor 2 and thus effective for preventing bonding failure and positional deviation of the control terminals 44. The semiconductor device A1 is provided with the control terminals 44 in the form of pin terminals extending in the z direction. This configuration allows the semiconductor device A1 to be smaller than a device having signal terminals extending along a plane orthogonal to the z direction as in the patent document. In short, the semiconductor device A1 is suitable for reducing the size in plan view.

In the semiconductor device A1, the insulating layer 61 of the bonding layer 6 is a film-like layer sandwiched between the adhesive layers 62 and 63. The bonding layer 6 of this configuration may be made of a double sided adhesive tape. The bonding layer 6 can stick the signal substrate 5 and the supporting conductor 2 together. This facilitates the process of bonding the signal substrate 5 to the supporting conductor 2 in the manufacture of the semiconductor device A1. In addition, the bonding layer 6 having the film-like insulating layer 61 as the substrate can be small in the length in the z direction. Given the small thickness of the bonding layer 6, any thickness variation is small. With the thickness variation of the bonding layer 6 ensured to be small, the semiconductor device A1 can reduce bonding failure and positional deviation of the control terminals 44.

For the semiconductor device A1, the insulating layer 61 of the bonding layer 6 is made of polyimide, for example. During operation of the semiconductor device A1, heat is generated by the semiconductor elements 1 being switched on and off. The heat of the semiconductor elements 1 is transferred to the supporting conductor 2. The insulating layer 61 of the semiconductor device A1 is thermally insulating and thus reduces the heat transfer from the supporting conductor 2 to the signal substrate 5. Thus, the semiconductor device A1 can reduce the heat transfer from the semiconductor elements 1 to the wires 73 to 76, which are bonded to the signal substrate 5 (the wiring layers 521 to 526). In short, the semiconductor device A1 can reduce the heat load on the wires 73 to 76.

In the semiconductor device A1, the first control terminals 45 are secured to the wiring layers 521 to 526 on the first signal substrate 5A and supported by the first conductive part 2A via the first signal substrate 5A. The first control terminals 45 are located farther in the x2 direction than the first switching elements 1A. Similarly, the second control terminals 46 are secured to the wiring layers 521 to 526 of the second signal substrate 5B and supported by the second conductive part 2B via the second signal substrate 5B. The second control terminals 46 are located farther in the x1 direction than the second switching elements 1B. The first control terminals 45, as well as the second control terminals 46, are spaced apart from each other in the y direction. That is, the first control terminals 45 are located in the regions corresponding to the first switching elements LA forming the upper arm circuit, and the second control terminals 46 are located in the regions corresponding to the second switching elements 1B forming the lower arm circuit. This arrangement is desirable for reducing parasitic inductance while also reducing the size of semiconductor device A1.

Next, semiconductor devices according to variations of the present disclosure will be described.

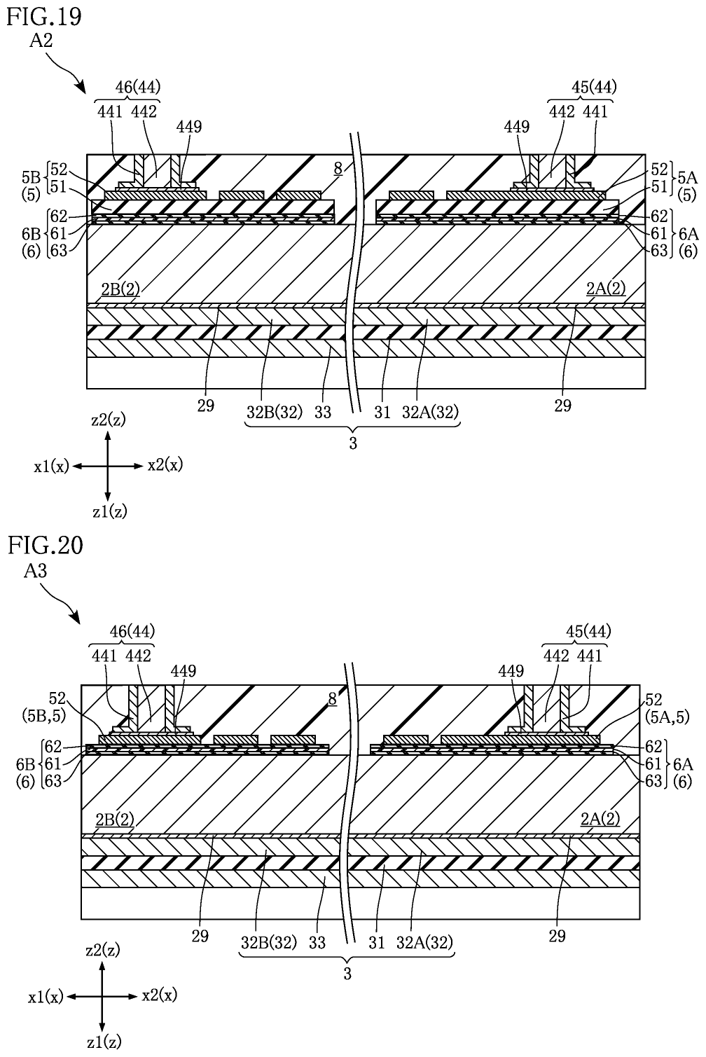

FIG. 19 shows a semiconductor device A2 according to a first variation. As shown in FIG. 19, the semiconductor device A2 differs from the semiconductor device A1 in that the signal substrate 5 (each of the first signal substrate 5A and the second signal substrate 5B) does not include the second metal layer 53.

In the semiconductor device A2, the signal substrate 5 does not include the second metal layer 53, so that the insulating substrate 51 is bonded to the supporting conductor 2 via the bonding layer 6. The insulating substrate 51 of the first signal substrate 5A is bonded to the first conductive part 2A by the first bonding body 6A, and the insulating substrate 51 of the second signal substrate 5B is bonded to the second conductive part 2B by the second bonding body 6B.

Similarly to the semiconductor device A1, the semiconductor device A2 includes the bonding layer 6, which is not solder, between the signal substrate 5 and the supporting conductor 2. This configuration serves to prevent the tilt of the wiring layers 521 to 526 relative to the supporting conductor 2. The semiconductor device A2 can therefore reduce bonding failure and positional deviation of the control terminals 44, thereby improving the reliability.

Similarly to the semiconductor device A1, the semiconductor device A2 uses the bonding layer 6 to bond the signal substrate 5 to the supporting conductor 2. In a configuration different from the semiconductor device A2, solder may be used instead of the bonding layer 6. However, soldering the signal substrate 5 to the supporting conductor 2 may be difficult unless the signal substrate 5 includes the second metal layer 53 as in the semiconductor device A1. In contrast to this and similar to the semiconductor device A1, the semiconductor device A2 uses the bonding layer 6 that includes the pair of adhesive layers 62 and 63 disposed on the opposite sides of the insulating substrate 51 in the z direction. This makes it possible to bond the signal substrate 5 to the supporting conductor 2 even if the insulating substrate 51 does not include the second metal layer 53. Yet, the signal substrate 5 including the second metal layer 53 has the following advantages over the signal substrate 5 not including the second metal layer 53. First, the second metal layer 53 has the effect of reducing warping of the signal substrate 5. Second, the second metal layer 53 has the effect of increasing the heat capacity of the signal substrate 5 and thus reducing the temperature rise of the signal substrate 5.

FIG. 20 shows a semiconductor device A3 according to a second variation. As shown in FIG. 20, the semiconductor device A3 differs from the semiconductor device A2 in that the signal substrate 5 (each of the first signal substrate 5A and the second signal substrate 5B) does not include the insulating substrate 51.

In the semiconductor device A3, the signal substrate 5 does not include the insulating substrate 51 and the second metal layer 53, so that the first metal layer 52 (the wiring layers 521 to 526) is bonded to the supporting conductor 2 via the bonding layer 6. The first metal layer 52 (the wiring layers 521 to 526) of the first signal substrate 5A is bonded to the first conductive part 2A by the first bonding body 6A, and the first metal layer 52 (the wiring layers 521 to 526) of the second signal substrate 5B is bonded to the second conductive part 2B by the second bonding body 6B.

The semiconductor device A3 includes the bonding layer 6, which is not solder, between the plurality of wiring layers 521 to 526 and the supporting conductor 2. This configuration serves to prevent the tilt of the wiring layers 521 to 526 relative to the supporting conductor 2. The semiconductor device A3 can therefore reduce bonding failure and positional deviation of the control terminals 44, thereby improving the reliability.

Similarly to the semiconductor devices A1 and A2, the semiconductor device A3 includes the bonding layer 6 that includes the insulating layer 61. This configuration makes it possible to omit the insulating substrate 51 between the plurality of wiring layers 521 to 526 and the supporting conductor 2 (each of the first conductive part 2A and the second conductive part 2B). Insulation between each of the wiring layers 521 to 526 and the supporting conductor 2 (the first conductive part 2A or the second conductive part 2B) is provided by the bonding layer 6 that bonds the wiring layers 521 to 526 and the supporting conductor 2 (each of the first conductive part 2A and the second conductive part 2B).

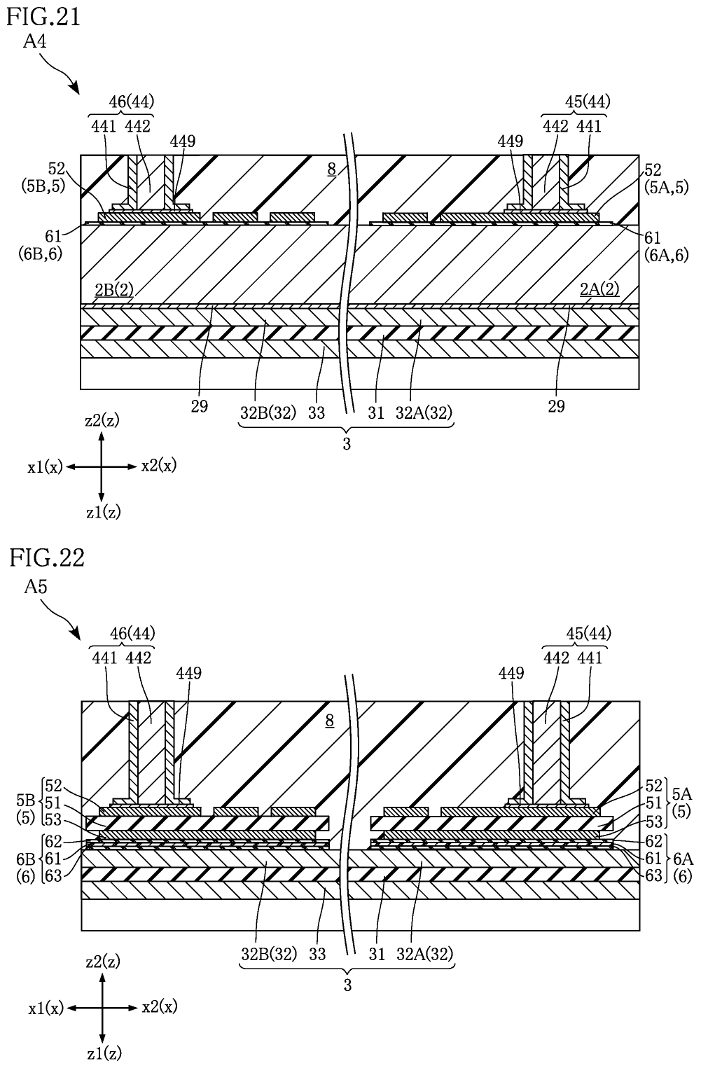

FIG. 21 shows a semiconductor device A4 according to a third variation. As shown in FIG. 21, the semiconductor device A4 differs from the semiconductor device A3 in that the bonding layer 6 (each of the first bonding body 6A and the second bonding body 6B) does not include the adhesive layers 62 and 63.

The bonding layer 6 (each of the first bonding body 6A and the second bonding body 6B) of the semiconductor device A4 includes an insulating layer 61 made of an adhesive insulating material. The insulating layer 61 of this configuration can bond the first metal layer 52 (each of the wiring layers 521 to 526) to the supporting conductor 2 while also insulating the first metal layer 52 (each of the wiring layers 521 to 526) and the supporting conductor 2.

Similarly to the semiconductor device A3, the semiconductor device A4 includes the bonding layer 6, which is not solder, between the plurality of wiring layers 521 to 526 and the supporting conductor 2, and can therefore prevent the tilt of the wiring layers 521 to 526 relative to the supporting conductor 2. The semiconductor device A4 can therefore reduce bonding failure and positional deviation of the control terminals 44, thereby improving the reliability.

In the example shown in FIG. 21, the semiconductor device A4 includes the signal substrate 5 is composed of the first metal layer 52 (the wiring layers 521 to 526). In a different configuration, however, the signal substrate 5 (each of the first signal substrate 5A and the second signal substrate 5B) may additionally include the insulating substrate 51 as in the semiconductor device A2 or include the insulating substrate 51 and the second metal layer 53 as in the semiconductor device A1.

FIG. 22 shows a semiconductor device A5 according to a fourth variation. As shown in FIG. 22, the semiconductor device A5 differs from the semiconductor device A1 in that the supporting conductor 2 (each of the first conductive part 2A and the second conductive part 2B) is not included.

The semiconductor device A5 does not include the supporting conductor 2, so that the signal substrate 5 is bonded to the first metal layer 32 of the supporting substrate 3 by the bonding layer 6. The first signal substrate 5A is bonded to the first part 32A by the first bonding body 6A, and the second signal substrate 5B is bonded to the second part 32B by the second bonding body 6B. In this variation, each of the first part 32A and the second part 32B is an example of the “supporting conductor”, the first part 32A is an example of the “first conductive part”, and the second part 32B is an example of the “second conductive part”. In this example, the power terminal 41 is electrically bonded to the first part 32A, and each power terminal 43 is electrically bonded to the second part 32B. In addition, the first switching elements LA are mounted on the first part 32A, and the second switching elements 1B are mounted on the second part 32B.

The semiconductor device A5 includes the bonding layer 6, which is not solder, between the signal substrate 5 and the first metal layer 32, and can therefore prevent the tilt of the wiring layers 521 to 526 relative to the first metal layer 32. The semiconductor device A5 can therefore reduce bonding failure and positional deviation of the control terminals 44, thereby improving the reliability.

In each of the semiconductor devices A1 to A4, the control terminals 44 are secured to the wiring layers 521 to 526, and the wiring layers 521 to 526 are supported by the supporting conductor 2 via the bonding layer 6. In a different configuration, the power terminals 41 to 43 may be secured to wiring layers different from the wiring layer 521 to 526, and these different wiring layers are supported by the supporting conductor 2 via the bonding layer 6. In such a configuration, each of the power terminals 41 to 43 is an example of the “terminal”.

In each of the semiconductor devices A1 to A5, the control terminals 44 (each of the first control terminals 45 and the second control terminals 46) is a press-fit terminal that includes a holder 441 and a metal pin 442. The control terminals 44, however, are not limited to this example. Each control terminal 44 (each of the first control terminals 45 and the second control terminals 46) may be made of a metal plate. The metal plate (the control terminals 44) may be processed by bending to extend in the z direction or without bending to extend in a plane orthogonal to the z direction (the x-y plane).

The semiconductor devices according to the present disclosure are not limited to the embodiments described above. The specific configuration of each part of a semiconductor device according to the present disclosure may suitably be designed and changed in various manners. The present disclosure includes the embodiments described in the following clauses.

Clause 1. A semiconductor device comprising:
a terminal including an electrically conductive tubular holder and a metal pin inserted into the holder;
a signal substrate including a wiring layer and an insulating substrate;
a supporting conductor supporting the wiring layer via the insulating substrate; and
a bonding layer interposed between the supporting conductor and the signal substrate,
wherein the insulating substrate includes an obverse surface and a reverse surface that are spaced apart in a thickness direction of the signal substrate,
the wiring layer is disposed on the obverse surface, and the terminal is secured to the wiring layer,
the holder is bonded to the wiring layer,
the metal pin extends in the thickness direction, and
the bonding layer includes an insulating layer that electrically insulates the signal substrate and the supporting conductor.

Clause 2. The semiconductor device according to Clause 1, wherein the bonding layer further includes a pair of adhesive layers disposed on opposite sides of the insulating layer in the thickness direction.

Clause 3. The semiconductor device according to Clause 2, wherein a length of each of the pair of adhesive layers in the thickness direction is at least 10% and at most 150% of a length of the insulating layer in the thickness direction.

Clause 4. The semiconductor device according to any one of Clauses 1 to 3, wherein a length of the insulating layer in the thickness direction is at least 0.1% and at most 1.0% of a length of the terminal in the thickness direction.

Clause 5. The semiconductor device according to any one of Clauses 1 to 4, wherein a length of the terminal in the thickness direction is at least 20 times and at most 30 times a length of the signal substrate in the thickness direction.

Clause 6. The semiconductor device according to any one of Clauses 2 to 5, wherein the insulating layer is a film-like layer.

Clause 7. The semiconductor device according to Clause 6, wherein the insulating layer contains a resin material.

Clause 8. The semiconductor device according to Clause 7, wherein the resin material is polyimide.

Clause 9. The semiconductor device according to any one of Clauses 1 to 8, wherein the insulating substrate contains a ceramic material.

Clause 10. The semiconductor device according to any one of Clauses 1 to 9, wherein the signal substrate includes a metal layer disposed on the reverse surface, and
the metal layer is bonded to the supporting conductor by the bonding layer.

Clause 11. The semiconductor device according to Clause 10, further comprising a semiconductor element electrically connected to the terminal,
wherein the semiconductor element is bonded to the supporting conductor.

Clause 12. The semiconductor device according to Clause 11, wherein the terminal is a control terminal for controlling the semiconductor element.

Clause 13. The semiconductor device according to Clause 12, wherein the supporting conductor includes a first conductive part and a second conductive part that are spaced apart from each other in a first direction orthogonal to the thickness direction,
the semiconductor element includes a first switching element bonded to the first conductive part and a second switching element bonded to the second conductive part,
the control terminal includes a first control terminal for controlling the first switching element and a second control terminal for controlling the second switching element,
the signal substrate includes a first signal substrate supporting the first control terminal and a second signal substrate supporting the second control terminal, and
the bonding layer includes a first bonding body bonding the first signal substrate to the first conductive part and a second bonding body bonding the second signal substrate to the second conductive part.

Clause 14. The semiconductor device according to Clause 13, wherein the first control terminal includes a first drive terminal for driving the first switching element and a first sensing terminal for sensing a conducting state of the first switching element, and
the second control terminal includes a second drive terminal for driving the second switching element and a second sensing terminal for sensing a conducting state of the second switching element.

Clause 15. The semiconductor device according to Clause 13 or 14, further comprising:
a first power terminal and a second power terminal to which a first power supply voltage is applied; and
a third power terminal to which a second power supply voltage is applied,
wherein the first power terminal is connected to the first conductive part and is electrically connected to the first switching element via the first conductive part,
the second power terminal is electrically connected to the second switching element, and
the third power terminal is connected to the second conductive part and is electrically connected to both the first switching element and the second switching element via the second conductive part.

Clause 16. The semiconductor device according to Clause 15, further comprising a resin member covering a portion of the first control terminal, a portion of the second control terminal, the first signal substrate, the second signal substrate, the first switching element and the second switching element,
wherein each of the first control terminal and the second control terminal protrudes from the resin member in the thickness direction.

Clause 17. The semiconductor device according to Clause 16, wherein the resin member includes: a resin obverse surface and a resin reverse surface spaced apart in the thickness direction; and a pair of resin side surfaces located between the resin obverse surface and the resin reverse surface in the thickness direction,
the pair of resin side surfaces are spaced apart from each other in the first direction,
the first power terminal and the second power terminal protrude from one of the pair of resin side surfaces in the first direction, and
the third power terminal protrudes from the other of the pair of resin side surfaces in the first direction.

Clause 18. The semiconductor device according to any one of Clauses 13 to 17, further comprising a supporting substrate supporting the first conductive part and the second conductive part.

### REFERENCE NUMERALS

A1 to A5: Semiconductor device 1: Semiconductor element
1A: First switching element 1B: Second switching element
10a: Element obverse surface 10b: Element reverse surface
11: First obverse-surface electrode
12: Second obverse-surface electrode
13: Third obverse-surface electrode
15: Reverse-surface electrode
17: Thermistor 19: Conductive bonding material
2: Supporting conductor
2A: First conductive part 2B: Second conductive part
201: Obverse surface
202: Reverse surface 29: Conductive bonding material
3: Supporting substrate
31: Insulating layer 32: First metal layer
32A: First part
32B: Second part 33: Second metal layer
41, 42, 43: Power terminal 44: Control terminal
441: Holder 442: Metal pin 449: Conductive bonding material
45: First control terminal 45A: First drive terminal
45B to 45E: First sensing terminal
46: Second control terminal
46A: Second drive terminal
46B to 46E: Second sensing terminal
5: Signal substrate 5A: First signal substrate
5B: Second signal substrate
51: Insulating substrate 51a: Obverse surface
51b: Reverse surface
52: First metal layer 521 to 526: Wiring layer
53: Second metal layer 6: Bonding layer
6A: First bonding body
6B: Second bonding body 61: Insulating layer
61a: Obverse surface
61b: Reverse surface 62, 63: Adhesive layers
71: First conductive member
711: Main part 711a: Opening 712: First connecting end
712a: Opening 713: Second connecting end
719: Conductive bonding material
72: Second conductive member 721: First wiring part
721a: First end
722: Second wiring part 722a: Recessed region
723: Third wiring part
724: Fourth wiring part 729: Conductive bonding material
73 to 76: Wire
8: Resin member 81: Resin obverse surface
82: Resin reverse surface
831 to 834: Resin side surface 832a: Recess
851: First projection
851a: First-projection end surface 851b: Recess
851c: Inner wall
852: Second projection 86: Resin cavity
88: Resin filled part

1. A semiconductor device comprising:
a terminal including an electrically conductive tubular holder and a metal pin inserted into the holder;
a signal substrate including a wiring layer and an insulating substrate;
a supporting conductor supporting the wiring layer via the insulating substrate; and
a bonding layer interposed between the supporting conductor and the signal substrate,
wherein the insulating substrate includes an obverse surface and a reverse surface that are spaced apart in a thickness direction of the signal substrate,
the wiring layer is disposed on the obverse surface, and the terminal is secured to the wiring layer,
the holder is bonded to the wiring layer,
the metal pin extends in the thickness direction, and
the bonding layer includes an insulating layer that electrically insulates the signal substrate and the supporting conductor.

2. The semiconductor device according to claim 1, wherein the bonding layer further includes a pair of adhesive layers disposed on opposite sides of the insulating layer in the thickness direction.

3. The semiconductor device according to claim 2, wherein a length of each of the pair of adhesive layers in the thickness direction is at least 10% and at most 150% of a length of the insulating layer in the thickness direction.

4. The semiconductor device according to claim 1, wherein a length of the insulating layer in the thickness direction is at least 0.1% and at most 1.0% of a length of the terminal in the thickness direction.

5. The semiconductor device according to claim 1, wherein a length of the terminal in the thickness direction is at least times and at most 30 times a length of the signal substrate in the thickness direction.

6. The semiconductor device according to claim 2, wherein the insulating layer is a film-like layer.

7. The semiconductor device according to claim 6, wherein the insulating layer contains a resin material.

8. The semiconductor device according to claim 7, wherein the resin material is polyimide.

9. The semiconductor device according to claim 1, wherein the insulating substrate contains a ceramic material.

10. The semiconductor device according to claim 1, wherein the signal substrate includes a metal layer disposed on the reverse surface, and
the metal layer is bonded to the supporting conductor by the bonding layer.

11. The semiconductor device according to claim 10, further comprising a semiconductor element electrically connected to the terminal,
wherein the semiconductor element is bonded to the supporting conductor.

12. The semiconductor device according to claim 11, wherein the terminal is a control terminal for controlling the semiconductor element.

13. The semiconductor device according to claim 12, wherein the supporting conductor includes a first conductive part and a second conductive part that are spaced apart from each other in a first direction orthogonal to the thickness direction,
the semiconductor element includes a first switching element bonded to the first conductive part and a second switching element bonded to the second conductive part,
the control terminal includes a first control terminal for controlling the first switching element and a second control terminal for controlling the second switching element,
the signal substrate includes a first signal substrate supporting the first control terminal and a second signal substrate supporting the second control terminal, and
the bonding layer includes a first bonding body bonding the first signal substrate to the first conductive part and a second bonding body bonding the second signal substrate to the second conductive part.

14. The semiconductor device according to claim 13, wherein the first control terminal includes a first drive terminal for driving the first switching element and a first sensing terminal for sensing a conducting state of the first switching element, and
the second control terminal includes a second drive terminal for driving the second switching element and a second sensing terminal for sensing a conducting state of the second switching element.

15. The semiconductor device according to claim 13, further comprising:
a first power terminal and a second power terminal to which a first power supply voltage is applied; and
a third power terminal to which a second power supply voltage is applied,
wherein the first power terminal is connected to the first conductive part and is electrically connected to the first switching element via the first conductive part,
the second power terminal is electrically connected to the second switching element, and
the third power terminal is connected to the second conductive part and is electrically connected to both the first switching element and the second switching element via the second conductive part.

16. The semiconductor device according to claim 15, further comprising a resin member covering a portion of the first control terminal, a portion of the second control terminal, the first signal substrate, the second signal substrate, the first switching element and the second switching element,
wherein each of the first control terminal and the second control terminal protrudes from the resin member in the thickness direction.

17. The semiconductor device according to claim 16, wherein the resin member includes: a resin obverse surface and a resin reverse surface spaced apart in the thickness direction; and a pair of resin side surfaces located between the resin obverse surface and the resin reverse surface in the thickness direction,
the pair of resin side surfaces are spaced apart from each other in the first direction,
the first power terminal and the second power terminal protrude from one of the pair of resin side surfaces in the first direction, and
the third power terminal protrudes from the other of the pair of resin side surfaces in the first direction.

18. The semiconductor device according to claim 13, further comprising a supporting substrate supporting the first conductive part and the second conductive part.
